(19) United States
(12) Patent Application Publication
(10) Pub. No.: US 2024/0363690 A1
(43) Pub. Date: Oct. 31, 2024

(54) GATE-ALL-AROUND (GAA) FIELD-EFFECT TRANSISTOR (FET) DEVICE EMPLOYING STRAIN MATERIAL IN INACTIVE GATE REGION(S) FOR APPLYING CHANNEL STRAIN FOR INCREASED CARRIER MOBILITY, AND RELATED FABRICATION METHODS

(71) Applicant: QUALCOMM Incorporated, San Diego, CA (US)

(72) Inventors: Haining Yang, San Diego, CA (US); Ming-Huei Lin, New Taipei City (TW); Junjing Bao, San Diego, CA (US)

(21) Appl. No.: 18/306,421

(22) Filed: Apr. 25, 2023

(51) Int. Cl. H01L 29/10; H01L 21/8238; H01L 27/092; H01L 29/06; H01L 29/423; H01L 29/66; H01L 29/775; H01L 29/786

(52) U.S. Cl. CPC H01L 29/1054; H01L 21/823807; H01L 27/092; H01L 29/0673; H01L 29/42392; H01L 29/66439; H01L 29/775; H01L 29/78696

(57) ABSTRACT

Gate-all-around (GAA) field-effect transistor (FET) device employing strain material structure in inactive gate region(s) of a gate for applying channel strain to the channel(s) of the GAA FET for increased carrier mobility. The GAA FET device includes a GAA P-type (P) FET (PFET) and a GAA N-type (N) FET (NFET) served by a gate with a strain material in the inactive gate region(s) of the gate adjacent to the active gates of the GAA NFET and GAA PFET. In this manner, the strain material applies strain to both the GAA NFET and GAA PFET channels in the elongated direction of the gate in a direction orthogonal to their channel directions between the respective sources and drains, so that a strain material of the same strain type can be used to increase carrier mobility of both the GAA NFET and GAA PFET alike.

### BACKGROUND

### I. Field of the Disclosure

The field of the disclosure relates to field-effect transistors (FETs) that can, for example, be employed in complementary metal oxide semiconductor (CMOS) cell circuits, and particularly gate-all-around (GAA) FETs.

### II. Background

Transistors are essential components in modern electronic devices, and large numbers of transistors are employed in integrated circuits (ICs) therein. For example, components such as central processing units (CPUs) and memory systems each employ a large quantity of transistors for logic circuits and memory devices.

As electronic devices become more complex in functionality, so does the need to include a greater number of transistors in such devices. But as electronic devices are provided in increasingly smaller packages, such as in mobile devices for example, there is a need to provide a greater number of transistors in a smaller IC chip. This increase in the number of transistors is achieved in part through continued efforts to miniaturize transistors in ICs (i.e., placing increasingly more transistors into the same amount of space). In particular, node sizes in ICs are being scaled down by a reduction in minimum metal line width in the ICs (e.g., 65 nanometers (nm), 45 nm, 28 nm, 20 nm, etc.). As a result, the gate lengths of planar transistors are also scalably reduced, thereby reducing the channel lengths of the transistors and interconnects. Reduced channel length in planar transistors has the benefit of increasing drive strength (i.e., increased drain current) and providing smaller parasitic capacitances resulting in reduced circuit delay. However, as channel length in planar transistors is reduced such that the channel length is of the same order of magnitude as the depletion layer widths, short channel effects (SCEs) can occur that degrade performance. More specifically, SCEs in planar transistors cause increased current leakage, reduced threshold voltage, and/or threshold voltage roll-off (i.e., reduced threshold voltage at shorter gate lengths), and therefore, reduced gate control.

In this regard, alternative FET designs to planar FETs have been developed. These alternative transistor designs provide for a gate material to wrap around at least a portion of a channel structure to provide better gate control over an active channel therein. Better gate control provides reduced current leakage and increased threshold voltage compared to a planar transistor of a similar footprint. One example of a gate around FET is a FinFET. A FinFET provides a channel structure formed by a thin semiconductor material “fin” disposed above the substrate between a source and the drain. The FinFET also includes a “wrap-around” gate that wraps around top and side portions of the fin to provide gate control of the channel formed by the channel structure. However, it has become difficult to scale down the size of FinFETs due to fabrication and performance limitations. In this regard, gate-all-around (GAA) FETs have been further developed. A GAA FET includes one or more nano channel structures of semiconductor material (e.g., nanowires or nanosheets) that are stacked in relation to each other and disposed between a source and a drain. Each nano channel structure forms part of the channel of the GAA FET. To provide better gate control of the channel, a gate material is disposed all around each of the channel structures as well as between adjacent channel structures. This provides even greater gate control in the GAA FET to provide reduced current leakage and increased threshold voltage compared to a planar FET and/or FinFET.

### SUMMARY OF THE DISCLOSURE

Aspects disclosed herein include a gate-all-around (GAA) field-effect transistor (FET) device employing a strain material in an inactive gate region(s) of a gate for applying channel strain the channel of the GAA FET for increased carrier mobility. Related fabrication methods are also disclosed. The GAA FET device includes a GAA FET that includes a semiconductor channel (“channel”) that includes one or more semiconductor channel structures (“channel structures”) (e.g., a nanosheet, a nanowire). A source and drain are disposed on opposite sides of the channel. An active portion of a gate or “active gate” is disposed around the semiconductor channel structures of the GAA FET to control the conductivity of its channel based on a voltage applied to the active gate. The portions of the gate that are outside and adjacent to the diffusion region in which the GAA FET is formed is the inactive portion or region of the gate also referred to as the “inactive gate region.” In exemplary aspects, to increase carrier mobility in the channel of the GAA FET, a strain material is disposed in one or more inactive gate regions of the gate adjacent to the active gate of the GAA FET. The strain material being disposed in the inactive gate region(s) of the gate of the GAA FET causes a strain to be applied in the elongated direction of the gate, which is in a direction orthogonal to its channel direction (e.g., channel length direction) between the source and the drain of the GAA FET. For example, it has been found that applying tensile strain to a GAA FET channel in a direction orthogonal to its channel direction between the source and the drain can increase carrier mobility in both a GAA P-type semiconductor material type (P-type) FET (PFET) and a GAA N-type semiconductor material (N-type) FET (NFET) alike. This is because strain applied to a channel of both a GAA PFET and GAA NFET in a direction orthogonal to their channel directions between their respective sources and drains will shift the lattice structure of their channels in the same direction. Thus, this technique of straining a GAA FET with a strain material disposed in an inactive gate region(s) of a gate of the GAA FET can be used interchangeably and compatibly in both GAA PFET and GAA NFET devices that include such a GAA FET(s) to increase their carrier mobility. This is opposed to, for example, applying different strains of compressive strain to a PFET and tensile strain to an NFET in their channel length or current flow directions, like is commonly provided in FinFETs, to increase carrier mobility.

It may also be more difficult to fabricate a GAA FET with a strain material that applies a strain in the channel length or current flow direction of the GAA FET. For example, as the node size of a GAA FET is reduced, it may be more difficult to fabricate a GAA FET with a strain material in the source/drain region and/or their extension regions that applies a strain to a GAA FET channel in the channel length or current flow direction. Being able to sufficiently strain a GAA FET channel to increase its carrier mobility may be particularly important since the surface crystalline orientation of a GAA FET channel formed on a wafer with a conventional surface crystalline orientation, may have an inherently weaker carrier mobility than other types of FETs, like FinFETs, with different channel surface crystalline orientations formed on the wafer.

In another exemplary aspect, the strain material structure(s) can be formed from a strain material filled in the inactive gate region(s) of a gate as a replacement portion of a gate. For example, the strain material can be filled in one or more gate cuts in an inactive gate region(s) of the gate to form the strain material structure(s). In this manner, an inactive gate region(s) of a gate can be repurposed to include a strain material structure to strain the channel of a GAA FET served by the gate to increase its carrier mobility.

In another exemplary aspect, a GAA FET device is provided that includes a GAA PFET and a GAA NFET both served by a gate with a strain material of the same strain type formed in the inactive gate region(s) of the gate. The GAA FET device may be provided as a cell circuit. The strain material structure(s) formed in the inactive gate region(s) of the gate has a strain material of the same strain type that applies the same type of a strain (e.g., a tensile strain) to both channels of the GAA PFET and GAA NFET in a direction orthogonal to their channel directions between their respective sources and drains. Thus, the same strain material can be provided in an inactive gate region(s) of the gate of the GAA FET and GAA NFET to apply the same type of strain in directions orthogonal to their channel directions between their respective sources and drains to increase the carrier mobility in both the GAA PFET and GAA NFET alike. For example, applying tensile strain to both channels of a GAA PFET and GAA NFET in a direction orthogonal to their channel directions between their respective sources and drains can increase carrier mobility of both the GAA PFET and GAA NFET alike. In another example, the GAA FET device can be part of a complementary metal oxide semiconductor (CMOS) circuit. For example, the GAA PFET and a GAA NFET can be provided in the GAA FET device to both be served by a common gate with a strain material structure(s) formed in the inactive gate region(s) of the gate to apply strain of the same strain type to both channels of the GAA PFET and the GAA NFET.

In another aspect, a conductor can be formed adjacent to a strain material structure(s) in the inactive gate region(s) of the gate that serves both a GAA PFET and GAA NFET in a GAA FET device in a cell circuit. This provides a conductive path around the strain material structure(s) to conductively couple the active gates of the GAA PFET and GAA NFET together. This may be useful for example, if the GAA PFET and GAA NFET that are served by the same gate need to have their respective gates coupled together to form a CMOS logic circuit (e.g., an inverter circuit).

In this regard, in one exemplary aspect, a gate-all-around (GAA) field-effect transistor (FET) device is provided. The GAA FET device comprises a semiconductor substrate. The GAA FEET device comprises a P-type semiconductor material (P) (P-type) diffusion region in the semiconductor substrate and an N-type semiconductor material (N) (N-type) diffusion region in the semiconductor substrate. The GAA FET device also comprises a gate adjacent to the semiconductor substrate and extending in a first direction. The gate comprises a first active gate region in the P-type diffusion region, a second active gate region in the N-type diffusion region, and one or more inactive gate regions each outside of the P-type diffusion region and outside of the N-type diffusion region. The GAA FET device also comprises a GAA NFET disposed in the P-type diffusion region. The GAA NFET comprises an N-type channel extending in a second direction orthogonal to the first direction, the N-type channel adjacent to a first inactive gate region of the one or more inactive gate regions, and a first active gate comprising at least a portion of the first active gate region of the gate surrounding the N-type channel. The GAA FET device also comprises a GAA PFET disposed in the N-type diffusion region. The GAA PFET comprises a P-type channel extending in the second direction, the P-type channel adjacent to a second inactive gate region of the one or more inactive gate regions, and a second active gate comprising at least a portion of the second active gate region of the gate surrounding the P-type channel. The GAA FET device also comprises a strain material of a first strain type in the first inactive gate region and the second inactive gate region.

In another exemplary aspect, a method of fabricating a GAA FET device is provided. The method comprises forming a P-type diffusion region in a semiconductor substrate. The method also comprises forming an N-type diffusion region in the semiconductor substrate. The method also comprises forming a GAA NFET comprising forming an N-type channel adjacent to the semiconductor substrate in the P-type diffusion region and extending in a second direction. The method also comprises forming a GAA PFET comprising forming a P-type channel adjacent to the semiconductor substrate in the N-type diffusion region and extending in the second direction. The method also comprises forming a gate adjacent to the semiconductor substrate extending in a first direction orthogonal to the second direction, wherein forming the gate further comprises forming a first active gate region of the gate in the P-type diffusion region comprising a first active gate surrounding the N-type channel, forming a second active gate region of the gate in the N-type diffusion region comprising a second active gate surrounding the P-type channel, and forming one or more inactive gate regions of the gate outside of the N-type diffusion region and outside of the P-type diffusion region, the one or more inactive gate regions comprising a first inactive gate region adjacent to the N-type channel and a second inactive gate region adjacent to the P-type channel. The method also comprises disposing a strain material of a first strain type in the first inactive gate region and the second inactive gate region.

### BRIEF DESCRIPTION OF THE FIGURES

FIGS. 1A and 1B are side perspective and side views, respectively, of an exemplary gate-all-around (GAA) field-effect transistor (FET) (GAA FET);

FIG. 2A is a top view of an exemplary cell circuit that includes a GAA FET device that includes a GAA P-type semiconductor material (P) FET (PFET) and GAA N-type semiconductor material (N) FET (NFET) that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in directions orthogonal to their channel directions between their respective sources and drains to increase their carrier mobility;

FIG. 2B is a cross-sectional side view of the cell circuit in FIG. 2A;

FIG. 3 is another top view of the GAA FET device in FIGS. 2A and 2B that includes multiple GAA PFET devices and GAA NFET devices that can be part of a complementary metal oxide semiconductor (CMOS) circuit, wherein the multiple GAA PFET devices and GAA NFET device have respective active gates provided by respective active regions of gates intersecting their diffusion regions, and wherein strain material is disposed in inactive gate regions of the gates to apply the same type of strain to the channels of the GAA PFET and GAA NFET in directions orthogonal to their channel directions between their respective sources and drains;

FIG. 4A is a top view of another exemplary GAA FET device similar to the GAA FET device in FIGS. 2A and 2B, but further includes a conductor formed adjacent to a strain material structure(s) in an inactive gate region of the gate disposed between the N-type and P-type diffusion regions and that is coupled to both a GAA PFET and GAA NFET to provide a conductive path around the strain material structure to conductively couple the active gates of the GAA PFET and GAA NFET together;

FIG. 4B is a cross-sectional side view of the GAA FET device in FIG. 4A;

FIG. 5 is another top view of the GAA FET device in FIGS. 4A and 4B that includes multiple GAA PFET devices and GAA NFET devices that can be part of a CMOS circuit, wherein the GAA FET device includes a conductor(s) formed adjacent to a strain material structure(s) in an inactive gate region(s) of the gate(s) each between N-type and P-type diffusion regions and that is coupled to both a GAA PFET and GAA NFET in a respective GAA PFET device and a GAA NFET device to provide a conductive path around the strain material structure to conductively couple the active gates of the GAA PFET and GAA NFET together;

FIG. 6 is a flowchart illustrating an exemplary process of fabricating a GAA FET device that includes a GAA PFET and GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in directions orthogonal to their channel directions between their respective sources and drains, including, but not limited to, the GAA FET devices in FIGS. 2A-5;

FIG. 7A-7D is a flowchart illustrating another exemplary process of fabricating a GAA FET device in a cell circuit that includes GAA PFET and a GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in directions orthogonal to their channel directions between their respective sources and drains, including, but not limited to, the GAA FET devices in FIGS. 2A-5;

FIGS. 8A-8G are exemplary fabrication stages during fabrication of the GAA FET device according to the exemplary fabrication process in FIGS. 7A-7D;

FIG. 9 is a block diagram of an exemplary processor-based system that can include a GAA FET device(s) that includes a GAA PFET and a GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in directions orthogonal to their channel directions between their respective sources and drains, including, but not limited to, the GAA FET devices in FIGS. 2A-5 and 8A-8G, and that can be fabricated according to the exemplary fabrication processes in FIGS. 6-7D; and

FIG. 10 is a block diagram of an exemplary wireless communications device that includes radio-frequency (RF) components that can include a GAA FET device(s) that includes GAA PFET and a GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in directions orthogonal to their channel directions between their respective sources and drains, including, but not limited to, the GAA FET devices in FIGS. 2A-5 and 8A-8G, and that can be fabricated according to the exemplary fabrication processes in FIGS. 6-7D.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a gate-all-around (GAA) field-effect transistor (FET) device employing a strain material in an inactive gate region(s) of a gate for applying channel strain the channel of the GAA FET for increased carrier mobility. Related fabrication methods are also disclosed. The GAA FET device includes a GAA FET that includes a semiconductor channel (“channel”) that includes one or more semiconductor channel structures (“channel structures”) (e.g., a nanosheet, a nanowire). A source and drain are disposed on opposite sides of the channel. An active portion of a gate or “active gate” is disposed around the semiconductor channel structures of the GAA FET to control the conductivity of its channel based on a voltage applied to the active gate. The portions of the gate that are outside and adjacent to the diffusion region in which the GAA FET is formed is the inactive portion or region of the gate also referred to as the “inactive gate region.” In exemplary aspects, to increase carrier mobility in the channel of the GAA FET, a strain material is disposed in one or more inactive gate regions of the gate adjacent to the active gate of the GAA FET. The strain material being disposed in the inactive gate region(s) of the gate of the GAA FET causes a strain to be applied in the elongated direction of the gate, which is in a direction orthogonal to its channel direction (e.g., channel length direction) between the source and the drain of the GAA FET. For example, it has been found that applying tensile strain to a GAA FET channel in a direction orthogonal to its channel direction between the source and the drain can increase carrier mobility in both a GAA P-type semiconductor material type (P-type) FET (PFET) and a GAA N-type semiconductor material (N-type) FET (NFET) alike. This is because strain applied to a channel of both a GAA PFET and GAA NFET in a direction orthogonal to their channel directions between their respective sources and drains will shift the lattice structure of their channels in the same direction. Thus, this technique of straining a GAA FET with a strain material disposed in an inactive gate region(s) of a gate of the GAA FET can be used interchangeably and compatibly in both GAA PFET and GAA NFET devices that include such a GAA FET(s) to increase their carrier mobility. This is opposed to, for example, applying different strains of compressive strain to a PFET and tensile strain to an NFET in their channel length or current flow directions, like is commonly provided in FinFETs, to increase carrier mobility.

In another exemplary aspect, a GAA FET device is provided that includes a GAA PFET and a GAA NFET both served by a gate with a strain material of the same strain type formed in the inactive gate region(s) of the gate. The GAA FET device may be provided as a cell circuit. The strain material structure(s) formed in the inactive gate region(s) of the gate has a strain material of the same strain type that applies the same type of a strain (e.g., a tensile strain) to both channels of the GAA PFET and GAA NFET in directions orthogonal to their channel directions between their respective sources and drains. Thus, the same strain material can be provided in an inactive gate region(s) of the gate of the GAA PFET and GAA NFET to apply the same type of strain in a direction orthogonal to their channel directions between their respective sources and drains to increase the carrier mobility in both the GAA PFET and GAA NFET alike. For example, applying tensile strain to both channels of a GAA PFET and GAA NFET in a direction orthogonal to their channel directions between their respective sources and drains can increase carrier mobility of both the GAA PFET and GAA NFET alike. In another example, the GAA FET device can be part of a complementary metal oxide semiconductor (CMOS) circuit. For example, the GAA PFET and a GAA NFET can be provided in the GAA FET device to both be served by a common gate with a strain material structure(s) formed in the inactive gate region(s) of the gate to apply strain of the same strain type to both channels of the GAA PFET and the GAA NFET.

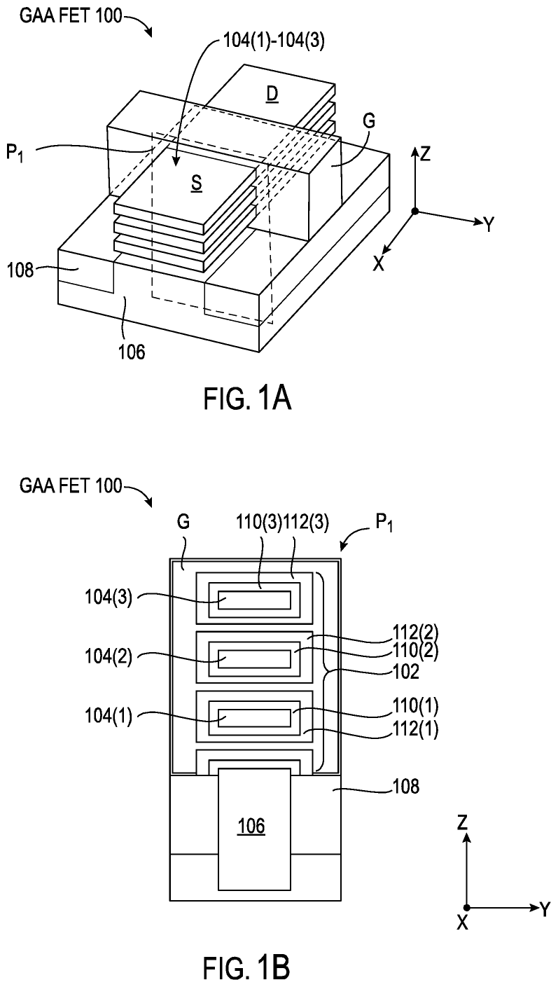

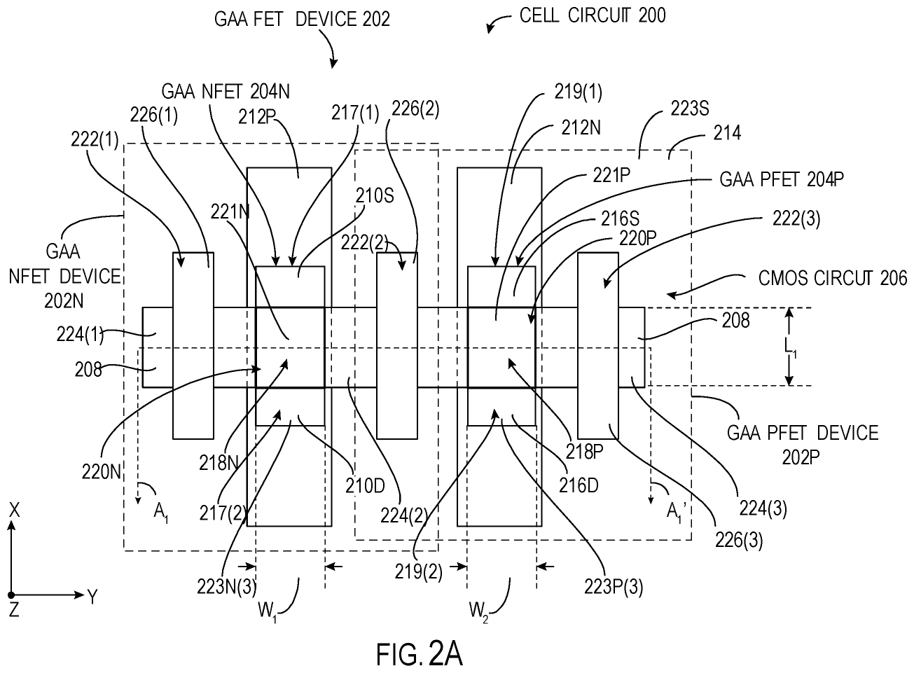

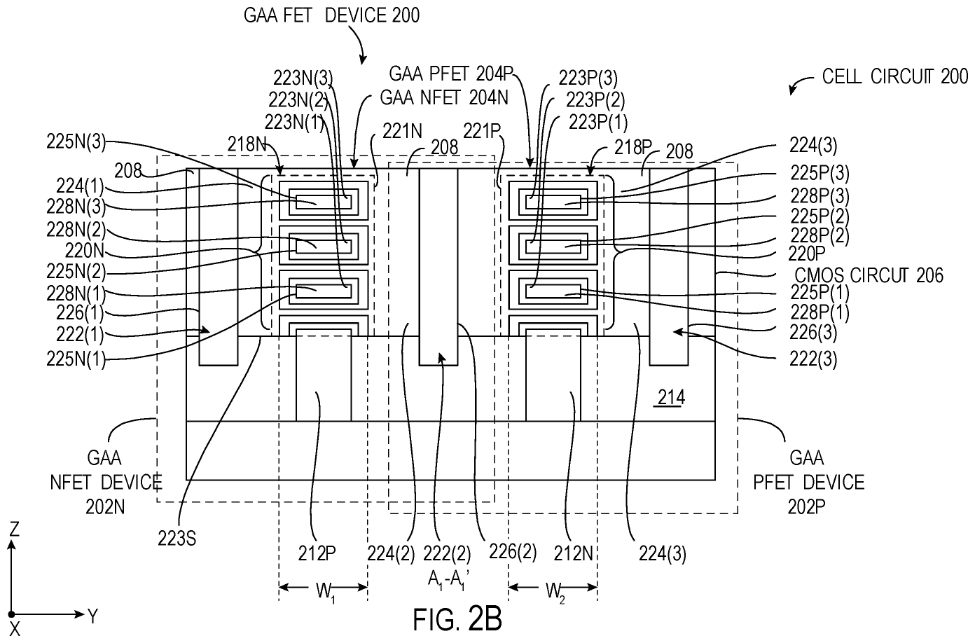

Before discussing examples of GAA FET devices that have a strain material structure(s) being formed in inactive gate regions of a gate of the same strain type to apply the same type of strain to the respective channels of a GAA PFET and GAA NFET in a direction orthogonal to their channel directions between their respective sources and drains to increase their carrier mobility starting at FIG. 2A, an exemplary GAA FET is discussed with regard to FIGS. 1A and 1B.

FIGS. 1A and 1B are side perspective and side views, respectively, of an exemplary GAA FET 100. The side view of the GAA FET 100 shown in FIG. 1B is across the plane P₁ of the GAA FET 100 shown in FIG. 1A. As shown in FIGS. 1A and 1B, the GAA FET 100 includes a semiconductor channel (“channel”) 102 that includes a plurality of channel structures 104(1)-104(3) that are of a semiconductor material (e.g., silicon (Si)). The semiconductor channel (“channel”) 102 is formed in a doped diffusion region 106 of a semiconductor substrate 108. The diffusion region 106 is doped with an N-type or P-type semiconductor material depending on whether the GAA FET 100 is a respective GAA P-type semiconductor material (P) FET (PFET) or GAA N-type semiconductor material (N) FET (NFET). The channel structures 104(1)-104(3) are configured to become conducting to allow current to flow between an adjacent source S and drain D disposed on opposite sides of the channel 102 when activated by a surrounding gate G. When a sufficient voltage at or exceeding a turn-on threshold voltage of the GAA FET 100 is applied to the gate G, an electric field is created in the channel structures 104(1)-104(3).

In this example, the gate G surrounding the channel structures 104(1)-104(3) extends in a first direction (Y-axis direction). The channel structures 104(1)-104(3) extend in a second direction (X-axis direction) that is orthogonal to the first direction (Y-axis direction). In this example, the channel structures 104(1)-104(3) are nanosheets which are nanostructures of semiconductor material. As shown in FIG. 1B, the gate G surrounds or is disposed “all-around” the individual channel structures 104(1)-104(3). The all-around gate G disposed around the channel structures 104(1)-104(3) provides better electrical control over the channel 102, and thus assists in reducing the leakage current and overcoming other short channel effects (SCEs) in the GAA FET 100. An interfacial layer 110(1)-110(3) is disposed around the respective channel structures 104(1)-104(3) followed by a respective high-K dielectric material layer 112(1)-112(3) to insulate the gate material of the gate G from the channel structures 104(1)-104(3).

With continuing reference to the GAA FET 100 in FIGS. 1A and 1B, it may be desired to enhance performance of the GAA FET 100 by increasing the carrier mobility in the channel 102 to increase its drive strength. In this regard, the carrier mobility of the GAA FET 100 in FIGS. 1A and 1B can be increased by imparting a strain to the channel structures 104(1)-104(3) in the second direction (X-axis direction) to stress (i.e., apply a stress force to) the channel structures 104(1)-104(3). For example, a strain material (e.g., Silicon Nitride (SiN)) can be disposed in the GAA FET 100 in and/or between the source S and/or drain D, and the channel structures 104(1)-104(3) to impart a strain on the channel structures 104(1)-104(3) in the second direction (X-axis direction). If the GAA FET 100 is a PFET, applying a compression strain applies a compression stress force to the GAA FET 100, which will increase its carrier mobility. On the other hand, if the GAA FET 100 is an NFET, applying a tensile strain applies a tensile stress force to the GAA FET 100, which will increase its carrier mobility.

However, as the node size of the GAA FET 100 may need to be reduced due to area constraints in integrated circuits (ICs), fabrication process limits may make it difficult or impossible to introduce a strain material in the GAA FET 100 to impart a strain on the channel structures 104(1)-104(3). This is because with the evolution of the design of the GAA FET 100 in FIGS. 1A and 1B, the channel 102 is expanding in width in the first direction (Y-axis direction) while the channel 102 is being reduced in length in the second direction (X-axis direction). This has the effect of reducing the available area between the source S and drain D and the channel 102 in which to dispose a strain material to impart a desired or sufficient strain on the channel structures 104(1)-104(3) in the second direction (X-axis direction) to effectively increase carrier mobility. Thus, providing a strain material between the source S/drain D and the channel 102 to apply a strain to the channel in the second direction (X-axis direction) becomes less effective to increase carrier mobility.

Thus, in exemplary aspects discussed in more detail below, to increase carrier mobility in GAA FETs, such as the GAA FET 100 in FIGS. 1A and 1B, the GAA FETs include a strain material structure of a strain material to apply the same type of strain to their respective channels to apply a stress force to their channels in a first direction of their channel width orthogonal to their channel directions between their respective sources and drains, to increase their carrier mobility. It may be easier to fabricate a GAA FET with such strain material structure, if the GAA FET has a reduced channel length with an expanded channel width orthogonal to the channel direction between its source and drain, such as due to reduction in GAA FET node size.

Also, in other exemplary aspects discussed in more detail below, it has been found that applying tensile strain to a channel of a GAA FET in directions orthogonal to their channel directions between their respective sources and drains can increase carrier mobility in both a GAA PFET and GAA NFET alike. This is because straining a GAA FET channel in a direction orthogonal to its channel direction between its source and drain can shift the lattice structure of its channel structure(s) in the same direction regardless of whether the GAA FET is a GAA PFET or GAA NFET. Thus, this technique of straining the channel of a GAA FET in a direction orthogonal to the channel direction between the source and the drain to increase carrier mobility can be used interchangeably and compatibly for a GAA PFET and GAA NFET alike. This is opposed to, for example, having to provide mechanisms to apply different types of strain such as compressive strain to GAA PFETs and tensile strain to GAA NFETs in their channel length or current flow directions to increase their carrier mobility.

In this regard, FIG. 2A is a top view of an exemplary cell circuit 200 that includes a GAA FET device 202, which in this example is a GAA NFET device 202N and a GAA PFET device 202P. The GAA NFET device 202N includes a GAA NFET 204N, and the GAA PFET device 202P includes a GAA PFET 204P. FIG. 2B is a cross-sectional side view of the cell circuit 200 in FIG. 2A across the A₁-A₁′ line. The cell circuit 200 in FIGS. 2A and 2B may be a complementary metal oxide semiconductor (CMOS) circuit 206 for example in which the GAA NFET 204N and the GAA PFET 204P are used to form a CMOS circuit (e.g., an inverter circuit). In this example, the GAA PFET 204P and the GAA NFET 204N share a common gate 208 that extends in a first direction (Y-axis direction). The GAA NFET 204N includes an N-type source region 210S and an N-type drain region 210D that are disposed in a P-type diffusion region 212P in a semiconductor substrate 214 (FIG. 2B). The gate 208 is also disposed adjacent to the semiconductor substrate 214. The GAA PFET 204P includes a P-type source region 216S and a P-type drain region 216D that are disposed in an N-type diffusion region 212N in the semiconductor substrate 214 (FIG. 2B). The P-type diffusion region 212P is a region in the semiconductor substrate 214 that is doped with a P-type semiconductor material to support the formation of the GAA NFET 204N. The N-type diffusion region 212N is a region in the semiconductor substrate 214 that is doped with an N-type semiconductor material to support the formation of the GAA PFET 204P. The GAA NFET 204N also includes an N-type channel 218N in the P-type diffusion region 212P that extends between the N-type source region 210S and the N-type drain region 210D in a second direction (X-axis direction) orthogonal to the first direction (Y-axis direction) of the gate 208.

As shown in FIG. 2A, the N-type source region 210S is disposed on a first side 217(1) of the N-type channel 218N in the second direction (X-axis direction), and the N-type drain region 210D is disposed on a second side 217(2) of the N-type channel 218N in the second direction (X-axis direction) opposite the first side 217(1). The GAA PFET 204P also includes a P-type channel 218P in the N-type diffusion region 212N that extends between the P-type source region 216S and the P-type drain region 216D also in the second direction (X-axis direction) orthogonal to the first direction (Y-axis direction) of the gate 208. As shown in FIG. 2A, the P-type source region 216S is disposed on a first side 219(1) of the P-type channel 218P in the second direction (X-axis direction), and the P-type drain region 216D is disposed on a second side 219(2) of the P-type channel 218P in the second direction (X-axis direction) opposite the first side 219(1). The gate 208 includes a first active gate region 220N that intersects the P-type diffusion region 212P wherein at least a portion of the first active gate region 220N that surrounds the N-type channel 218N forms a first active gate 221N for the GAA NFET 204P. The gate 208 also includes a second active gate region 220P that intersects the N-type diffusion region 212N wherein at least a portion of the second active gate region 220P that surrounds the P-type channel 218P forms a second active gate 221P for the GAA PFET 204P. An active gate region is a region in a diffusion area in which a gate material is disposed adjacent to a semiconductor channel of a transistor (e.g., a FET) to actively control the flow of current in the channel. In the example of a GAA FET, the active gate region is a region in a diffusion area in which a gate material is disposed around its channel to actively control the flow of current in the channel.

With regard to the GAA NFET 204N, to increase carrier mobility of its N-type channel 218N, a strain material 222(1), 222(2) is disposed in at least a portion of respective inactive gate regions 224(1), 224(2) of the gate 208 adjacent to and on each of the respective first and second sides 217(1), 217(2) of the N-type channel 218N in the first direction (Y-axis direction). An inactive gate region is a region of a gate outside (e.g., not coupled) of a diffusion area wherein a transistor is formed. Thus, the inactive gate regions 224(1), 224(2) of the gate 208 are regions of the gate 208 that are outside of the P-type and N-type diffusion region 212P, 212N. In this example, the inactive gate regions 224(1), 224(2) of the gate 208 are outside of (i.e., do not intersect) the P-type and N-type diffusion regions 212P, 212N in the first direction (Y-axis direction) and second direction (X-axis direction). The inactive gate region 224(2) is a common inactive gate region to both the GAA NFET 204N and the GAA PFET 204P in that the inactive gate region 224(2) is both adjacent to and between the GAA NFET 204N and the GAA PFET 204P in the first direction (Y-axis direction), between their respective N-type and P-type diffusion regions 212P, 212N. In this example, the strain material 222(1), 222(2) strains the N-type channel 218N with first and second respective strains of the same strain type by applying respective first and second stress forces to the gate 208 which in turn applies the respective first and second stress forces to the first active gate region 220N surrounding the N-type channel 218N. This increases the carrier mobility of the GAA NFET 204N.

Similarly, as discussed in more detail below, with regard to the GAA PFET 204P, to increase carrier mobility of its P-type channel 218P, a strain material 222(2), 222(3) is disposed in at least a portion of respective inactive gate regions 224(2), 224(3) of the gate 208 adjacent to and on each of the respective first and second sides 219(1), 219(2) of the P-type channel 218P in the first direction (Y-axis direction). The inactive gate regions 224(2), 224(3) of the gate 208 are also outside of the P-type and N-type diffusion regions 212P, 212N. In this example, the strain material 222(2), 222(3) strains the P-type channel 218P with second and third respective strains of the same strain type by applying respective second and third stress forces to the gate 208 which in turn applies the respective second and third stress forces to the second active gate region 220P surrounding the P-type channel 218P. This increases the carrier mobility of the GAA PFET 204P. In this example, the strain material 222(2) disposed in the inactive gate region 224(2) is between and adjacent to both the N-type channel 218N and P-type channel 218P of the respective GAA NFET 204N and GAA PFET 204P. Thus, the strain material 222(2) is a common strain material 222(2) that applies strain of the same strain type to both the N-type channel 218N and P-type channel 218P of the respective GAA NFET 204N and GAA PFET 204P in the first direction (Y-axis direction).

In this example, with continued reference to FIGS. 2A and 2B, the strain material 222(1), 222(2) is disposed in the inactive gate regions 224(1), 224(2) of the gate 208 to strain the N-type channel 218N in the first direction (Y-axis direction) of its channel direction along the channel width W₁ of the N-type channel 218N orthogonal to the second direction (X-axis direction) of the channel length L₁ between the N-type source region 210S and the N-type drain region 210D in the second direction (X-axis direction), to increase the carrier mobility of the GAA NFET 208N. Also in this example, the strain material 222(2), 222(3) is disposed in the inactive gate regions 224(2), 224(3) of the gate 208 to strain the P-type channel 218P in the first direction (Y-axis direction) of its channel width W₂ orthogonal to the second direction (X-axis direction) of its channel direction along the channel length L₁ between the P-type source region 216S and the P-type drain region 216D to increase the carrier mobility of the GAA PFET 204P. In this manner, as the channel widths W₁, W₂ of the respective NFET and PFET devices 202N, 202P in the first direction (Y-axis direction) increases, it may become easier from a fabrication process standpoint to dispose the strain material 222(1)-222(3) in the respective inactive gate regions 224(1)-224(3) of the gate 208 to strain the N-type channel 218N and the P-type channel 218P of the GAA NFET 204N and the GAA PFET 204P. This allows the N-type channel 218N and P-type channel 218P of the GAA NFET 204N and the GAA PFET 204P to be strained to increase their carrier mobility if it is not desired or feasible to include a strain material in the NFET and PFET devices 202N, 202P that applies a stress force on the N-type channel 218N and the P-type channel 218P of the GAA NFET 204N and GAA PFET 204P in their channel width directions in the first direction (Y-axis direction) orthogonal to the directions of their channel directions according to their channel lengths L₁ in the second direction (X-axis direction) between their respective N-type and P-type source regions 210S, 216S, and N-type and P-type drain regions 210D, 216D.

Also, in this non-limiting example of NFET and PFET devices 202N, 202P in FIGS. 2A and 2B, the strain material 222(1)-222(3) is configured to apply a tensile strain to both the respective N-type channel 218N and P-type channel 218P of the GAA NFET 204N and GAA PFET 204P. For example, the strain material 222(1)-222(3) could be Silicon Nitride (SiN) as a non-limiting example. It has been found that applying tensile strain to the both respective N-type channel 218N and P-type channel 218P of the GAA NFET 204N and GAA PFET 204P in the first direction (Y-axis direction) orthogonal to the direction of their channel lengths L₁ between their respective N-type and P-type source regions 210S, 216S, and N-type and P-type drain regions 210D, 216D in the second direction (X-axis direction) can increase carrier mobility in both a GAA NFET 204N and GAA PFET 204P alike. This is because tensile straining the N-type channel 218N and P-type channel 218P of the GAA NFET 204N and GAA PFET 204P in the first direction (Y-axis direction) will shift the lattice structure of the N-type channel 218N and P-type channel 218P in the same direction. Thus, this technique of tensile straining both the N-type channel 218N and P-type channel 218P of the GAA NFET 204N and GAA PFET 204P in the first direction (Y-axis direction) orthogonal to the direction of their channel lengths L₁ between their respective N-type and P-type source regions 210S, 216S, and N-type and P-type drain regions 210D, 216D to increase their carrier mobility can be used interchangeably and compatibly for both the GAA NFET 204N and GAA PFET 204P alike. This is opposed to, for example, having to provide mechanisms to apply different types of strain to an NFET and PFET in a FET device, such as a FinFET device, in order to increase carrier mobility of both the NFET and PFET.

For example, in GAA NFET 204N and GAA PFET 204P, the N-type channel 218N and P-type channel 218P have surfaces parallel to the semiconductor substrate 214 in horizontal directions (X-axis and Y-axis directions). This is due to the physical orientation of the nanosheets of the N-type channel 218N and P-type channel 218P in this example. Thus, the crystalline orientation of the surfaces of the N-type channel 218N and P-type channel 218P will be the same as the crystalline orientation of the surface of the semiconductor substrate 214 (e.g., 001 crystalline orientation). The directions of the channel widths W₁, W₂ of the respective N-type channel 218N and P-type channel 218P are the first direction (Y-axis direction) orthogonal to the direction (X-axis direction) of their channel lengths L₁ between their respective N-type source 210S and N-type drain 210D, and P-type source 216S and P-type drain 216D. It has been found that applying the same type of strain to the both respective N-type channel 218N and P-type channel 218P of the GAA NFET 204N and GAA PFET 204P in the first direction (Y-axis direction) orthogonal to the direction of their channel lengths L₁ in the second direction (X-axis direction) can increase carrier mobility in both a GAA NFET 204N and GAA PFET 204P alike. This is because applying the same type of strain to the N-type channel 218N and P-type channel 218P of the GAA NFET 204N and GAA PFET 204P in the first direction (Y-axis direction) will shift the lattice structure of the N-type channel 218N and P-type channel 218P in the same direction. Thus, including the same type of strain material 222(1)-222(3) in the gate 208, that is elongated in the first direction (Y-axis direction) applies a strain to the N-type channel 218N and P-type channel 218P of the GAA NFET 204N and GAA PFET 204P in the first direction of their channel widths W₁, W₂ (Y-axis direction) to increase carrier mobilities of the GAA NFET 204N and GAA PFET 204P alike.

With continuing reference to FIGS. 2A and 2B, in this example, the strain material 222(1)-222(3) forms respective strain material structures 226(1)-226(3) that are disposed the respective inactive gate regions 224(1)-224(3) of the gate 208. Note that although the strain material structures 226(1), 226(2) are formed on each side of the GAA NFET 204N in the first direction (Y-axis direction) in FIGS. 2A and 2B, such is not required. For example, a single strain material structure of the strain material structures 226(1), 226(2) could be formed on just one side of the GAA NFET 204N in the first direction (Y-axis direction). Likewise, although the strain material structures 226(2), 226(3) are formed on each side of the GAA PFET 204P in the first direction (Y-axis direction) in FIGS. 2A and 2B, such is not required. For example, a single strain material structure of the strain material structures 226(2), 226(3) could be formed on just one side of the GAA PFET 204P in the first direction (Y-axis direction).

Also, with continuing reference to FIGS. 2A and 2B, the strain material structures 226(1)-226(3) can also extend outside any or all of the respective inactive gate regions 224(1)-224(3), but such is not required. In the example in FIGS. 2A and 2B, the strain material structures 226(1)-226(3) extend outside of the respective inactive gate regions 224(1)-224(3) in the second direction (X-axis direction). Also note that as shown in FIG. 2B, the strain material structures 226(1), 226(2) can extend adjacent to and parallel to the N-type channel 218N of the GAA NFET 204N in a third direction (Z-axis direction) and below the N-type channel 218N in the third direction (Z-axis direction) into the semiconductor substrate 214. Similarly, as shown in FIG. 2B, the strain material structures 226(2), 226(3) can extend adjacent to and parallel to the P-type channel 218P of the GAA PFET 204P in the third direction (Z-axis direction) and below the P-type channel 218P in the third direction (Z-axis direction) into the semiconductor substrate 214. The strain material structures 226(1)-226(3) could also not extend outside of the respective inactive gate regions 224(1)-224(3) in the second direction (X-axis direction) and be contained within one or more respective inactive gate regions 224(1)-224(3) of the gate 208.

With reference to FIG. 2B, note that in this example, the N-type channel 218N of the GAA NFET 204N includes three(3) N-type channel structures 228N(1)-228N(3) that are each an N-type semiconductor material structure surrounded by the first active gate region 220N of the gate 208. The P-type channel 218P of the GAA PFET 204P includes three(3) P-type channel structures 228P(1)-228P(3) that are each a P-type semiconductor material structure surrounded by the second active gate region 220P of the gate 208. In this example, the N-type channel structures 228N(1)-228N(3) and/or the P-type channel structures 228P(1)-228P(3) can be nanosheets, but could also be nanowires or nanoslabs as other examples. A nanosheet is a thin, flat layer of semiconductor material (e.g., Si) that is used to create the channel of a GAA FET. A nanosheet in a GAA FET can be made of a semiconductor material (e.g., Si), and can be just a few atoms thick in the third direction (Z-axis direction). A nanoslab for a GAA FET is a thin, rectangular-shaped layer of semiconductor material (e.g., Si) that can also be used to create the channel of a GAA FET. Like a nanosheet, a nanoslab can be just a few atoms thick in the third direction (Z-axis direction). A nanowire for a for a GAA FET is a thin, cylindrical-shaped structure of semiconductor material (e.g., Si) that can also be used to create the channel of a GAA FET. Like a nanosheet and a nanoslab, a nanowire can be just a few atoms thick in the third direction (Z-axis direction).

With continuing reference to FIGS. 2A and 2B, in this example of the GAA FET device 202 of the GAA NFET 204N and GAA PFET 204P, the channel direction of the N-type channel 218N and P-type channel 218P have a crystalline orientation direction of <110> in this example, which has been shown to have enhanced carrier mobility performance. The surface 223S of the semiconductor substrate 214 and the major surfaces 223N(1)-223N(3), 223P(1)-223P(3) of N-type and P-type channel structures 228 (N)(1)-228N(3), 228P(1)-228P(3) oriented in the horizontal direction (in X- and Y-axes directions) parallel with the semiconductor substrate 214 have a crystalline orientation of (001). The major surfaces 223N(1)-223N(3), 223P(1)-223P(3) have more surface area than the minor surfaces 225N(1)-225N(3), 225P(1)-225P(3) of the N-type and P-type channel structures 228N(1)-228N(3), 228P(1)-228P(3) oriented in the vertical direction (X-and Z-axes directions). Most of the conductance in the N-type channel 218N and P-type channel 218P will be on the major surfaces 223N(1)-223N(3), 223P(1)-223P(3) of the N-type and P-type channel structures 228N(1)-228N(3), 228P(1)-228P(3), as opposed to the minor surfaces 225N(1)-225N(3), 225P(1)-225P(3). It has been found that with the orientation of the major surfaces 223N(1)-223N(3), 223P(1)-223P(3) of the N-type and P-type channel structures 228N(1)-228N(3), 228P(1)-228P(3), the same type of strain can be applied to the N-type and P-type channel structures 228N(1)-228N(3), 228P(1)-228P(3) in the first direction (Y-axis direction) orthogonal to the channel direction of the N-type and P-type channel structures 228N(1)-228N(3), 228P(1)-228P(3) between their respective N-type and P-type source regions 210S, 216S, to their respective N-type and P-type drain regions 210D, which increases carrier mobility of both the GAA NFET 204N and GAA PFET 204P alike. As discussed above, this strain type can be a tensile strain type.

This is in contrast to NFET and PFET FinFET devices fabricated from structures of similar crystalline orientations. In such NFET and PFET FinFET devices, the channel direction of their channels may also have a crystalline orientation direction of <110> for enhanced carrier mobility performance and formed on a substrate surface having a crystalline orientation of (001). However, in NFET and PFET FinFET devices, their major surfaces are oriented in a vertical direction (in X- and X-axes directions) perpendicular to the horizontal orientation of the major surfaces of a GAA FET, like the GAA NFET 204N and GAA PFET 204P in FIGS. 2A and 2B. Thus in this example, the major surfaces of the NFET and PFET FinFETs will have a crystalline orientation of (110), like the minor surfaces 225N(1)-225N(3), 225P(1)-225P(3) of the GAA NFET 204N and GAA PFET 204P in FIGS. 2A and 2B. The minor surfaces of the NFET and PFET FinFETs will have a crystalline orientation of (001) like the major surfaces 223N(1)-223N(3), 223P(1)-223P(3) of the GAA NFET 204N and GAA PFET 204P in FIGS. 2A and 2B. Thus, in NFET and PFET FinFETs, most of the conductance in their channels will be on their vertically-oriented major surfaces, in contrast with most of the conductance in N-type and P-type channels 218N, 218P of the GAA NFET 204N and GAA PFET 204P in FIGS. 2A and 2B being horizontally oriented parallel with the semiconductor substrate 214. It has been found that with the vertical orientation (Z-axis direction) of the major surfaces of the NFET and PFET FinFETs, the same type of strain cannot be applied to their channels in either the first direction (Y-axis direction) or the second direction (X-axis) of their channel and increase the carrier mobility of the NFET and PFET FinFETs alike. The NFET and PFET FinFETs could be strained similarly in a vertical direction (Z-axis direction) to increase the carrier mobility of the NFET and PFET FinFETs alike, but such is not practical to implement in a fabrication process. Also note that with regard to the cell circuit 200 in FIGS. 2A and 2B, although both the GAA NFET and GAA PFET devices 202N, 202P include the respective strain material structures 226(1)-226(2), 226(2)-226(3) to apply a strain to the N-type and P-type channels 218N, 218P of the respective GAA NFET 204N and GAA PFET 204P, such is not required. For example, only one of the strain material structures 226(1), 226(2) could be included in the GAA NFET device 202N as an alternative example. Also, only one of the strain material structures 226(2), 226(3) could be included in the GAA PFET device 202P as an alternative example.

As discussed above with regard to FIGS. 2A and 2B, the GAA NFET and GAA PFET devices 202N, 202P that include the respective strain material 222(1)-222(2), 222(2)-222(3) to apply a strain to the N-type and P-type channels 218N, 218N of the respective GAA NFET 204N and GAA PFET 204P can be provided in the CMOS circuit 206.

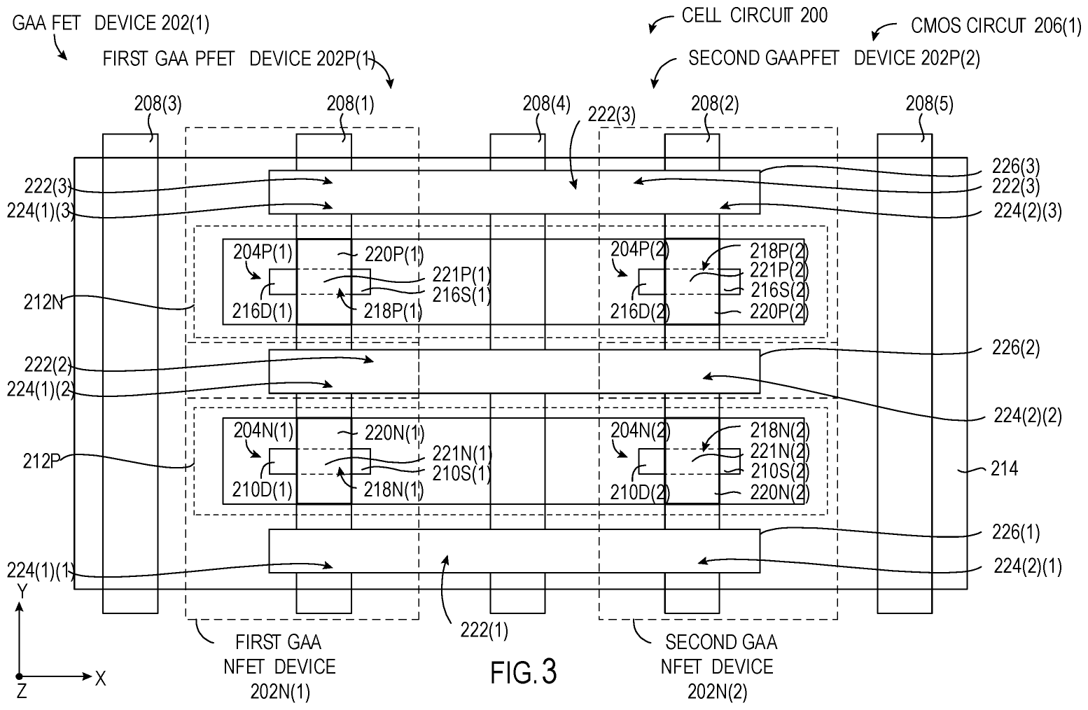

In this regard, FIG. 3 is a top view of another cell circuit 200(1) similar to the cell circuit 200 in FIGS. 2A and 2B. The cell circuit 200(1) includes a CMOS circuit 206(1) that includes a plurality of GAA FET devices like the GAA FET device 202 in FIGS. 2A and 2B, as the first and second GAA FET devices 202(1), 202(2). The first GAA FET device 202(1) includes a first GAA NFET device 202N(1) and a first GAA PFET device 202P(1), and the second GAA FET device 202(2) includes a second GAA NFET device 202N(2) and a second GAA PFET device 202P(2). The first and second GAA NFET devices 202N(1), 202N(2) are like the GAA NFET device 202N in FIGS. 2A and 2B. The first and second GAA PFET devices 202P(1), 202P(2) are like the GAA PFET device 202P in FIGS. 2A and 2B. The first and second GAA NFET devices 202N(1), 202N(2) each include respective first and second GAA NFETs 204N(1), 204N(2) that are like the GAA NFET 204N in FIGS. 2A and 2B. The first and second GAA PFET devices 202P(1), 202P(2) each include respective first and second GAA PFETs 204P(1), 204P(2) that are like the GAA PFET 204P in FIGS. 2A and 2B.

Common elements between the GAA NFET and GAA PFET devices 202N, 202P in FIGS. 2A and 2B and the first and second GAA NFET devices 202N(1), 202N(2) and the first and second GAA PFET devices 202P(1), 202P(2) in FIG. 3 are shown with common element numbers and are not re-described.

As shown in FIG. 3, the first GAA NFET 204N(1) and the first GAA PFET 204P(1) share a common, first gate 208(1) that extends in a first direction (Y-axis direction). The second GAA NFET 204N(2) and the second GAA PFET 204P(2) share a common, second gate 208(2) that extends in the first direction (Y-axis direction). The cell circuit 200(1) includes dummy gates 208(3)-208(5) that are adjacent to the respective first and second GAA NFET devices 202N(1), 202N(2) and first and second GAA PFET devices 202P(1), 202P(2). The first and second GAA NFETs 204N(1), 204N(2) include respective first and second N-type source regions 210S(1), 210S(2) and first and second P-type drain regions 210D(1), 210D(2) that are disposed in the P-type diffusion region 212P in the semiconductor substrate 214. The gates 208(1)-208(5) are also disposed adjacent to the semiconductor substrate 214. The first and second GAA PFETs 204P(1), 204P(2) include respective first and second P-type source regions 216S(1), 216S(2) and first and second P-type drain regions 216D(1), 216D(2) that are disposed in the N-type diffusion region 212N in the semiconductor substrate 214. The first and second GAA NFETs 204N(1), 204N(2) also include respective first and second N-type channels 218N(1), 218N(2) in the P-type diffusion region 212P that extend between the respective first and second N-type source regions 210S(1), 210S(2) and the first and second N-type drain regions 210D(1), 210D(2) in a second direction (X-axis direction) orthogonal to the first direction (Y-axis direction) of the first and second gates 208(1), 208(2). The first and second GAA PFETs 204P(1), 204P(2) also include respective first and second P-type channels 218P(1), 218P(2) in the N-type diffusion region 212N that extend between the respective first and second P-type source regions 216S(1), 216S(2) and the first and second P-type drain regions 216D(1), 216D(2) also in the second direction (X-axis direction) orthogonal to the first direction (Y-axis direction) of the first and second gates 208(1), 208(2).

With continuing reference to FIG. 3, the first and second gates 208(1), 208(2) include respective first active gate regions 220N(1), 220N(2) that intersect the P-type diffusion region 212P and provide respective first active gates 221N(1), 221N(2) for the respective first and second GAA NFETs 204N(1), 204N(2). The first and second gates 208(1), 208(2) also include respective second active gate regions 220P(1), 220P(2) that intersect the N-type diffusion region 212N and provide respective second active gates 221P(1), 221P(2) for the respective first and second GAA PFETs 204P(1), 204P(2).

With regard to the first and second GAA NFETs 204N(1), 204N(2), to increase carrier mobility of their first and second N-type channels 218N(1), 218N(2), a strain material 222(1), 222(2) is provided in respective strain material structures 226(1), 226(2) that are disposed in at least a portion of respective inactive gate regions 224(1)(1)-224(1)(2), 224(2)(1)-224(2)(2) of the respective first and second gates 208(1), 208(2) adjacent to the first and second N-type channels 218N(1), 218N(2). The inactive gate regions 224(1)(1)-224(1)(2), 224(2)(1)-224(2)(2) of the respective first and second gates 208(1), 208(2) are regions of the first and second gates 208(1), 208(2) that are outside of the P-type and N-type diffusion region 212P, 212N. In this example, the inactive gate regions 224(1)(1)-224(1)(2), 224(2)(1)-224(2)(2) of the respective first and second gates 208(1), 208(2) are outside of (i.e., do not intersect) the P-type and N-type diffusion region 212P, 212N in the first and second directions (Y-axis and X-axis directions). In this example, the strain material 222(1), 222(2) in the respective inactive gate regions 224(1)(1)-224(1)(2), 224(2)(1)-224(2)(2) strains the first and second N-type channels 218N(1), 218N(2) that causes a stress force (e.g., tensile stress force) to be imparted on the first and second gates 208(1), 208(2) which in turn applies a stress force to the first active gate regions 220N(1), 220N(2) surrounding the respective first and second N-type channels 218N(1), 218N(2). This increases the carrier mobility of the GAA NFETs 208N(1), 208N(2).

Similarly, with regard to the first and second GAA PFETs 204P(1), 204P(2), to increase carrier mobility of their first and second P-type channels 218P(1), 218P(2), a strain material 222(2), 222(3) is provided in respective strain material structures 226(2), 226(3) that are disposed in at least a portion of respective inactive gate regions 224(1)(2)-224(1)(3), 224(2)(2)-224(2)(3) of the respective first and second gates 208(1), 208(2) adjacent to the respective first and second P-type channels 218P(1), 218P(2). The inactive gate regions 224(1)(2)-224(1)(3), 224(2)(2)-224(2)(3) of the respective first and second gates 208(1), 208(2) are also outside of the P-type and N-type diffusion regions 212P, 212N. In this example, the strain material 222(2), 222(3) strains the first and second P-type channels 218P(1), 218P(2) by applying a stress force (e.g., tensile stress force) to the first and second gates 208(1), 208(2) which in turn applies a stress force to the second active gate regions 220P(1), 220P(2) surrounding the respective first and second P-type channels 218P(1), 218P(2). This increases the carrier mobility of the first and second GAA PFETs 204P(1), 204P(2).

The inactive gate regions 224(1)(2), 224(2)(2) are adjacent to and between the respective N-type diffusion region 212N and P-type diffusion region 212P. The inactive gate regions 224(1)(1), 224(2)(1) are adjacent to the N-type diffusion region 212N such that the first and second GAA NFETs 204N(1), 204(N)(2) are disposed between the inactive gate regions 224(1)(2), 224(2)(2) and 224(1)(1), 224(2)(1) in the first direction (Y-axis direction). The inactive gate regions 224(1)(3), 224(2)(3) are adjacent to the P-type diffusion region 212P such that the first and second GAA PFETs 204P(1), 204P(2) are disposed between the inactive gate regions 224(1)(3), 224(2)(3) and 224(1)(2), 224(2)(2) in the first direction (Y-axis direction). With the strain material 222(1)-222(3) disposed in the respective inactive gate regions 224(1)(1)-224(2)(1), 224(1)(2)-224(2)(2), 224(1)(3)-224(2)(3) disposed on each side of the respective first and second N-type channels 218N(1), 218N(2) and first and second P-type channels 218P(1), 218P(2), the strain material 222(1)-222(3) strains the respective first and second N-type channels 218N(1), 218N(2) and first and second P-type channels 218P(1), 218P(2) to increase the carrier mobility of the first and second GAA NFETs 204N(1), 204N(2) and first and second GAA PFETs 204P(1), 204P(2).

Note that the previous discussion of other features and options for the GAA NFET and GAA PFET devices 202N, 202P and their respective GAA NFET 204N and GAA PFET 204P in FIGS. 2A and 2B can be provided for the respective first and second GAA NFET devices 202N(1), 202N(2), and the first and second GAA PFET devices 202P(1), 202P(2) in FIG. 3 and their respective first and second GAA NFETs 204N(1), 204N(2) and first and second GAA PFETs 204P(1), 204P(2).

As shown in the CMOS circuit 206(1) in FIG. 3, the first GAA NFET 204N(1) and first GAA PFET 204P(1) have respective first and second active gate regions 220N(1), 220P(1) from the same first gate 208(1). Similarly, the second GAA NFET 204N(2) and second GAA PFET 204P(2) have respective first and second active gate regions 220N(2), 220P(2) from the same second gate 208(2). The introduction of the strain material structure 226(2) between the P-type and N-type diffusion regions 212P, 212N and disposed in the first gate 208(1) may act as a gate cut in the first gate 208(1) such that the first and second active gate regions 220N(1), 220P(1) are not conductively coupled to each other. Likewise, the introduction of the strain material structure 226(2) between the P-type and N-type diffusion regions 212P, 212N and disposed in the second gate 208(2) may act as a gate cut in the second gate 208(2) such that the first and second active gate regions 220N(2), 220P(2) are also not conductively coupled to each other. However, it may be desired to couple the first and second active gate regions 220N(1), 220P(1) of the respective first GAA NFET 204N(1) and first GAA PFET 204P(1) together, and/or couple the first and second active gate regions 220N(2), 220P(2) of the respective second GAA NFET 204N(2) and second GAA PFET 204P(2) together to form CMOS circuits.

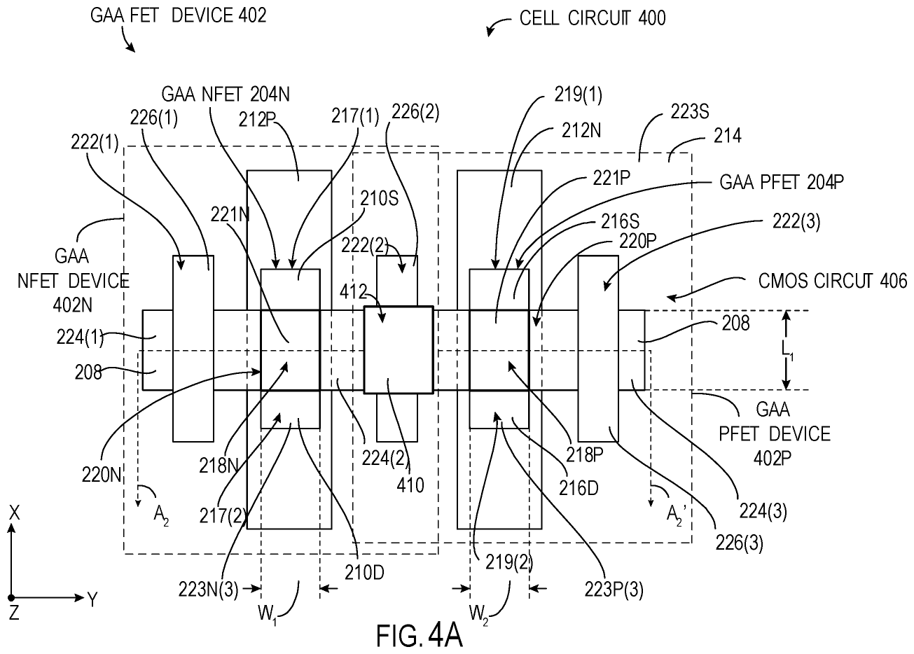

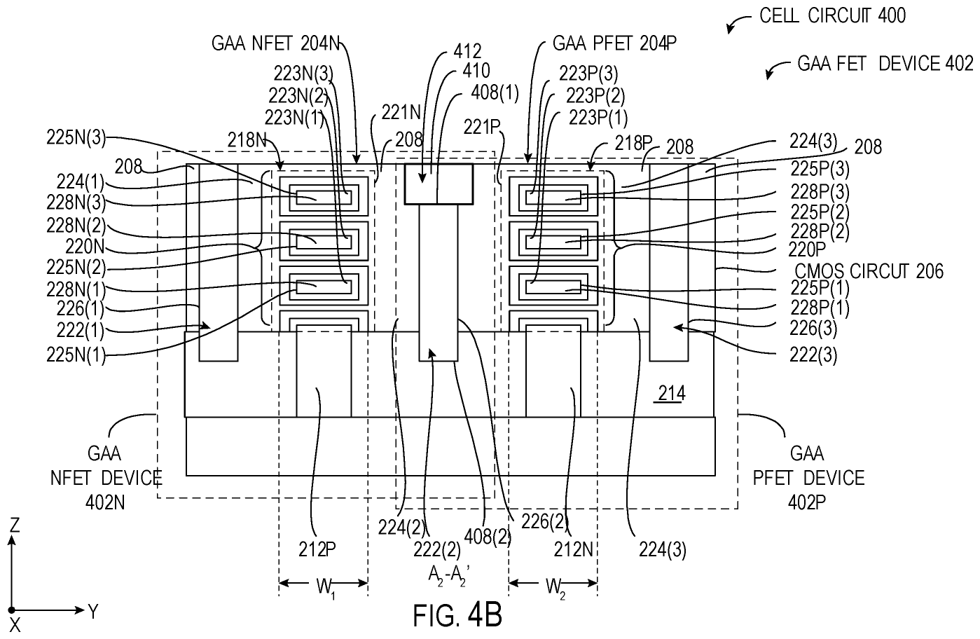

In this regard, FIGS. 4A and 4B are top and cross-sectional side views of another exemplary cell circuit 400 similar to the cell circuit 200 in FIGS. 2A and 2B. FIG. 4B is a cross-sectional side view of the cell circuit 400 in FIG. 4A across the A₂-A₂′ line. The cell circuit 400 in FIGS. 4A and 4B includes a CMOS circuit 406 that is similar to the CMOS circuit 206 in FIGS. 2A and 2B. The CMOS circuit 406 in FIGS. 4A and 4B includes GAA NFET and GAA PFET devices 402N, 402P that are similar to the GAA NFET and GAA PFET devices 202N, 202P in FIGS. 2A and 2B. The GAA NFET and GAA PFET devices 402N, 402P include the respective GAA NFET 204N and GAA PFET 204P in FIGS. 2A and 2B, and thus, the GAA NFET 204N and GAA PFET 204P are not re-described. Also, common elements between the cell circuit 400 in FIGS. 4A and 4B and the cell circuit 200 in FIGS. 2A and 2B are shown with common element numbers, and thus, the description of such in FIGS. 2A and 2B above is also applicable for the GAA NFET 204N and GAA PFET 204P in FIGS. 4A and 4B. However, as shown in FIGS. 4A and 4B, a conductive material structure 410 that includes a conductive material 412 (e.g., metal material) is disposed in and/or adjacent to the strain material 222(2) in the strain material structure 226(2) and the gate 208. As shown in FIG. 4B, the conductive material 412 couples the first and second active gates 221N, 221P of the respective GAA NFET 204N and GAA PFET 204P together if it is desired to form a CMOS circuit 406 in the cell circuit 400 that has the first and second active gates 221N, 221P of the GAA NFET 204N and GAA PFET 204P coupled together.

As also shown in FIG. 4B, the strain material structure 226(2) has a first end 408(1) and a second end 408(2) on an opposite end of the first end 408(1) in the third direction (Z-axis direction). The second end 408(2) of the strain material structure 226(2) is adjacent to the semiconductor substrate 214. The conductive material 412 in the conductive material structure 410 is disposed in the first inactive gate region 224(2) of the gate 208 and coupled to the first end 408(1) of the strain material structure 226(2) in this example. Note that the conductive material structure 410 could be alternatively disposed between the first end 408(1) and the second end 408(2) of the strain material structure 226(2) to couple the first and second active gates 221N, 221P of the GAA NFET 204N and GAA PFET 204P together. Note that the conductive material structure 410 could be alternatively disposed at the second end 408(2) of the strain material structure 226(2) to couple the first and second active gates 221N, 221P of the GAA NFET 204N and GAA PFET 204P together.

FIG. 5 is another top view of another cell circuit 400(1) that is similar to the cell circuit 400 in FIGS. 4A and 4B, and includes a GAA FET device 402(1) that forms a CMOS circuit 406(1). Common elements between the cell circuit 400(1) in FIG. 5 and the cell circuit 200(1) in FIG. 3 are shown with common element numbers and are not re-described. The discussion of these common elements in the cell circuit 200(1) in FIG. 3 is applicable to the common elements in the cell circuit 400(1) in FIG. 5. However, the cell circuit 400(1) in FIG. 5 includes two(2), first and second conductive material structures 410(1), 410(2) each with respective conductive material 412(1), 412(2) (e.g., metal material) that are similar to the conductive material structure 410 and its conductive material 412 in FIGS. 4A and 4B. The first conductive material structure 410(1) couples the respective first and second active gates 221N(1), 221P(1) of the respective first GAA NFET 204N(1) and first GAA PFET 204P(1) of the respective first GAA NFET device 402N(1) and first GAA PFET device 402P(1) together. In this manner, the respective first and second active gates 221N(1), 221P(1) of the respective first GAA NFET 204N(1) and first GAA PFET 204P(1) can be coupled together without being isolated by the strain material structure 226(2) to form part of the CMOS circuit 406(1). The second conductive material structure 410(2) couples the respective first and second active gates 221N(2), 221P(2) of the respective second GAA NFET 204N(2) and second GAA PFET 204P(2) of the respective second GAA NFET device 402N(2) and second GAA PFET device 402P(2) together. In this manner, the respective first and second active gates 221N(2), 221P(2) of the respective second GAA NFET 204N(2) and second GAA PFET 204P(2) can be coupled together without being isolated by the strain material structure 226(2) to form part of the CMOS circuit 406(1).

The first and second GAA NFET devices 402N(1), 402N(2) in the cell circuit 400(1) in FIG. 5 are similar to the first and second GAA NFET devices 202N(1), 202N(2) in the cell circuit 200(1) in FIG. 3, except that the first and second GAA NFET devices 402N(1), 402N(2) include the respective first and second conductive material structures 410(1), 410(2). The first and second GAA PFET devices 402P(1), 402P(2) in the cell circuit 400(1) in FIG. 5 are similar to the first and second GAA PFET devices 202P(1), 202P(2) in the cell circuit 200(1) in FIG. 3, except that the first and second GAA PFET devices 402P(1), 402P(2) include the respective first and second conductive material structures 410(1), 410(2).

Fabrication processes can be employed to fabricate a GAA FET device that includes a GAA FET that has an active gate provided by an active region of a gate intersecting a diffusion region where the GAA FET is formed, and wherein a strain material is disposed in an inactive gate region of the gate to apply a strain to the channel of the GAA FET in a direction orthogonal its channel direction between their respective N-type and P-type source regions 210S, 216S, and N-type and P-type drain regions 210D, 216D to increase its carrier mobility, including, but not limited to, the GAA FET devices 202, 202(1), 402, 402(1) in FIGS. 2A-5.

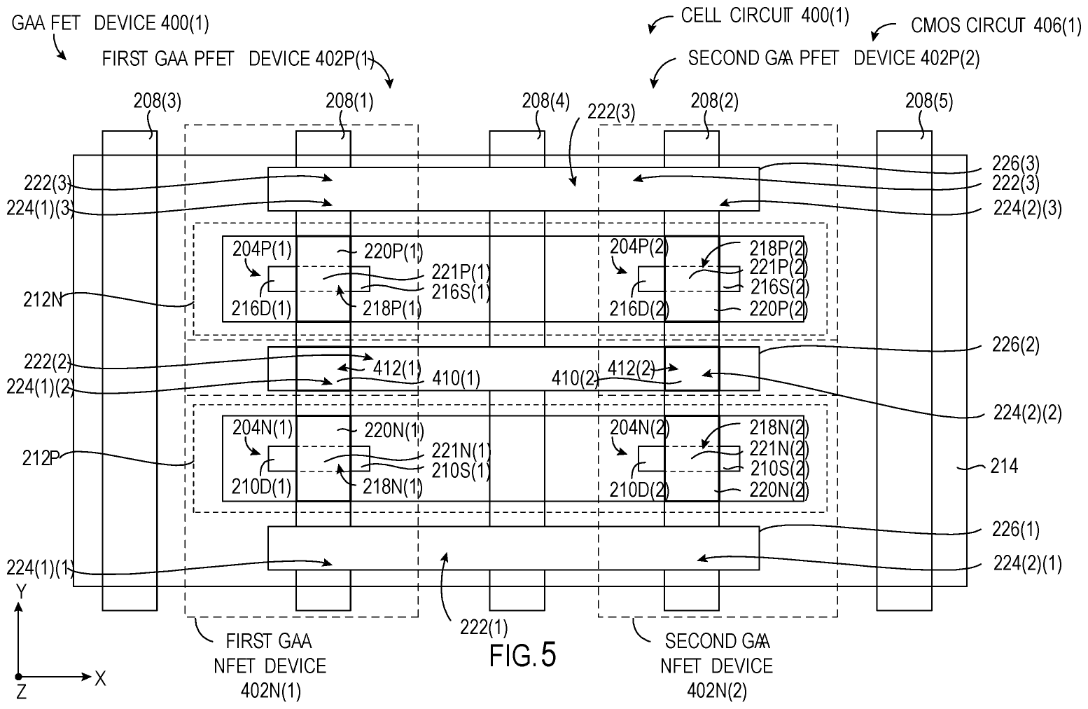

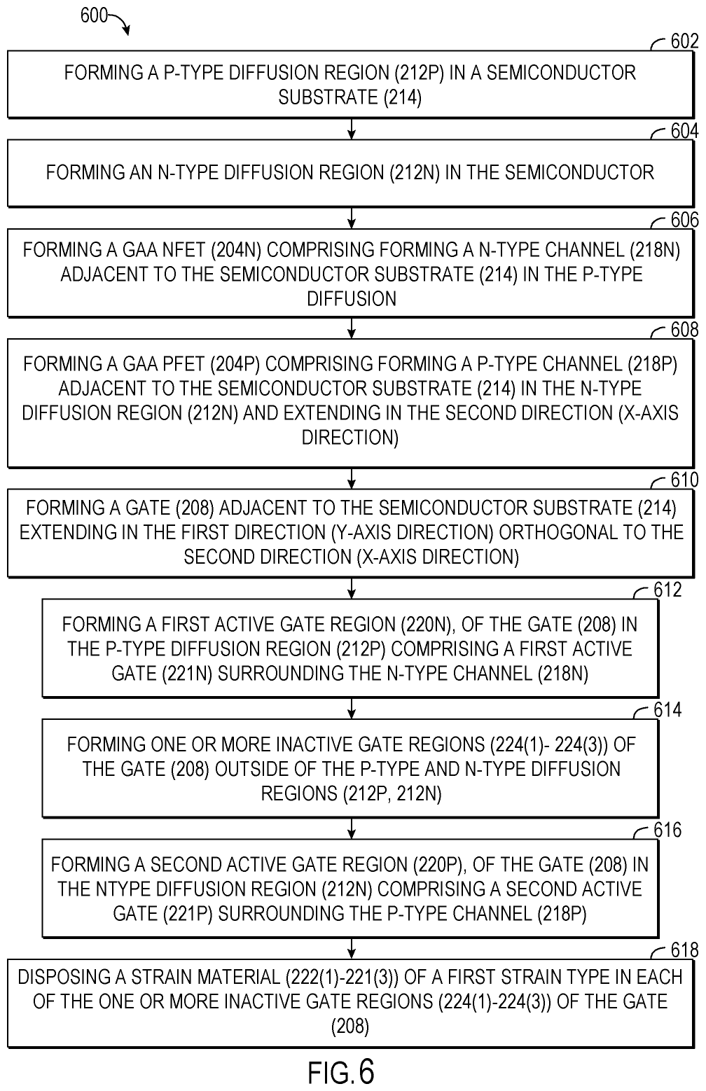

In this regard, FIG. 6 is a flowchart illustrating an exemplary fabrication process 600 of fabricating a GAA FET device that includes a GAA PFET and GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in a direction orthogonal to their channel length directions between their respective sources and drains to increase their carrier mobility, including, but not limited to, the GAA FET devices 200, 200(1), 400, 400(1) in FIGS. 2A-5. The fabrication process 600 can be employed to fabricate a CMOS circuit like the CMOS circuits 206, 206(1), 406, 406(1) in FIGS. 2A-5 to fabricate one or more GAA NFET devices 202N, 202N(1), 202N(2), 402N, 402N(1), 402N(2) and/or GAA PFET devices 202P, 202P(1), 202P(2), 402P, 402P(1), 402P(2). The fabrication process 600 in FIG. 6 is discussed with regard to a GAA FET device 202(1), 402(1) in FIGS. 3 and-5, but note that the fabrication process 600 in FIG. 6 is not limited to fabricating GAA FET devices like the FET devices 202(1), 402(2) in FIGS. 3 and 5.

In this regard, an exemplary step in the fabrication process 600 for fabricating the FET device 202, 402 can include forming a P-type diffusion region 212P in a semiconductor substrate 214 (block 602 in FIG. 6). A next exemplary step in the fabrication process 600 can include forming an N-type diffusion region 212N in the semiconductor substrate 214 (block 604 in FIG. 6). A next exemplary step in the fabrication process 600 can also include forming a GAA NFET 204N (block 606 in FIG. 6). Forming the GAA NFET 204N can include forming an N-type channel 218N adjacent to the semiconductor substrate 214 in the P-type diffusion region 212P extending in a second direction (X-axis direction) (block 606 in FIG. 6). A next exemplary step in the fabrication process 600 can also include forming a GAA PFET 204P (block 608 in FIG. 6). Forming the GAA PFET 204P can include forming a P-type channel 218P adjacent to the semiconductor substrate 214 in the N-type diffusion region 212N and extending in the second direction (X-axis direction) (block 608 in FIG. 6). A next exemplary step in the fabrication process 600 can include forming a gate 208 adjacent to the semiconductor substrate 214 and extending in the first direction (Y-axis direction) orthogonal to the second direction (X-axis direction) (block 610 in FIG. 6). Forming the gate 208 can include forming a first active gate region 220N, of the gate 208 in the P-type diffusion region 212P comprising a first active gate 221N surrounding the N-type channel 218N (block 612 in FIG. 6). Forming the gate 208 can also include forming a second active gate region 220P, of the gate 208 in the N-type diffusion region 212N comprising a second active gate 221P surrounding the P-type channel 218P (block 614 in FIG. 6). Forming the gate 208 can also include forming one or more inactive gate regions 224(1)-224(3) of the gate 208 outside of the P-type and N-type diffusion regions 212P, 212N (block 616 in FIG. 6). A next exemplary step in in the fabrication process 600 can include disposing a strain material 222(1)-221(3) of a first strain type in each of the one or more inactive gate regions 224(1)-224(3) of the gate 208 (block 618 in FIG. 6).

Other fabrication processes can also be employed to fabricate GAA FET devices that include a GAA PFET and GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in a direction orthogonal to their channel lengths between their respective sources and drains to increase their carrier mobility, including, but not limited to, the GAA FET devices 200, 200(1), 400, 400(1) in FIGS. 2A-5.

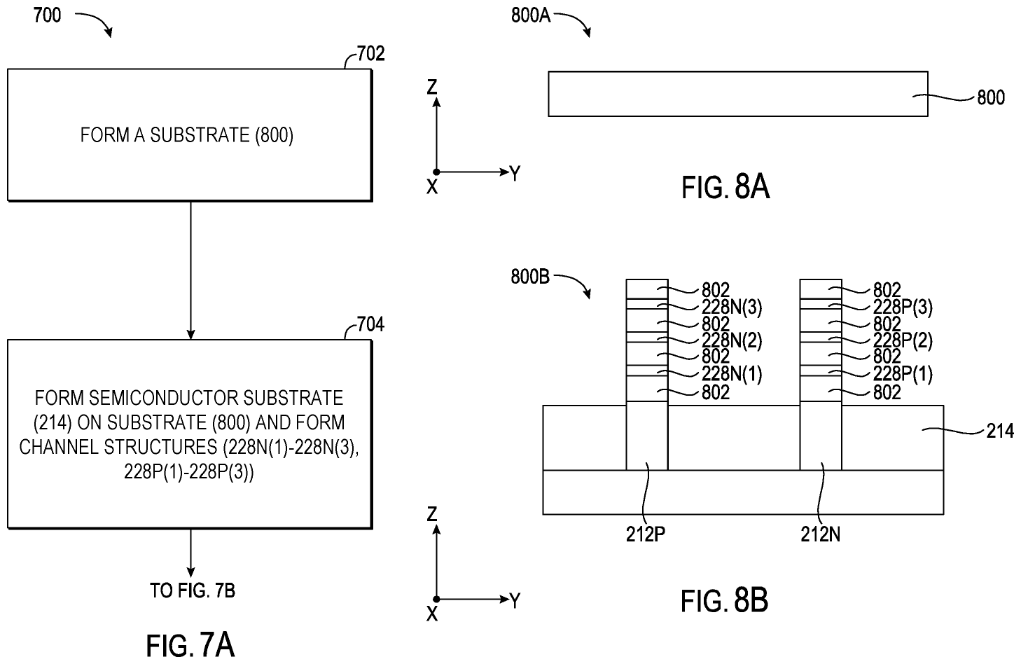

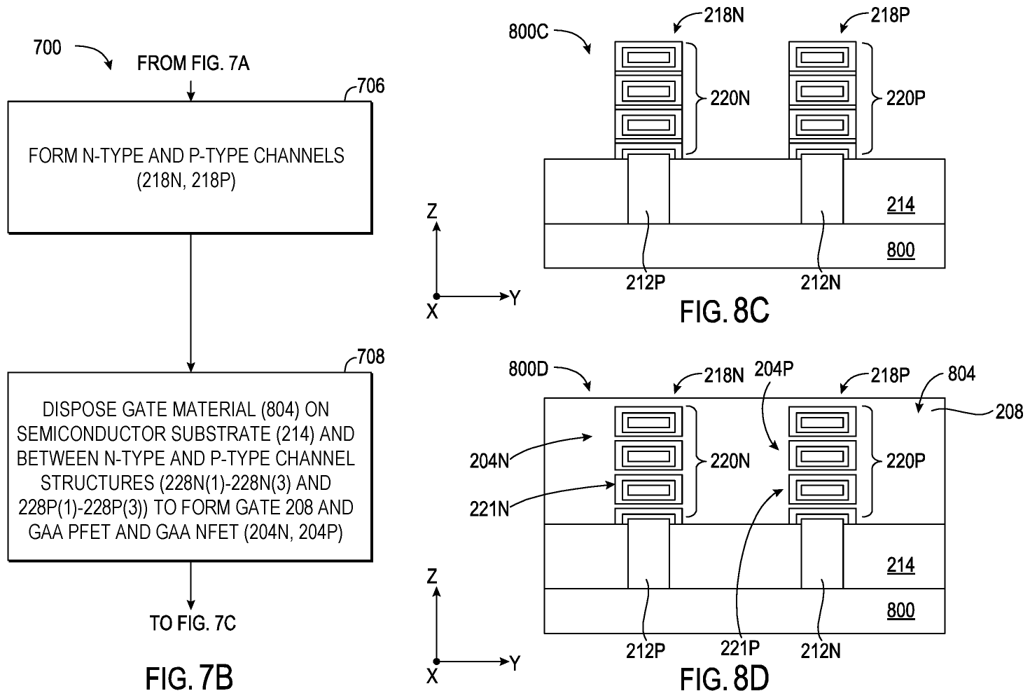

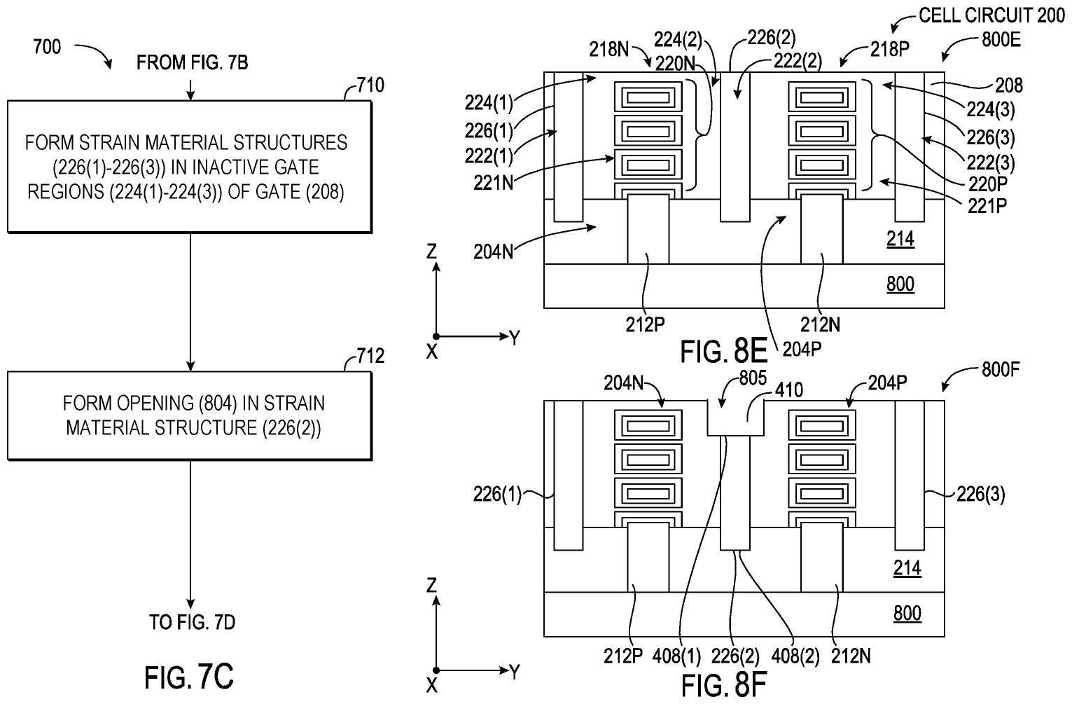

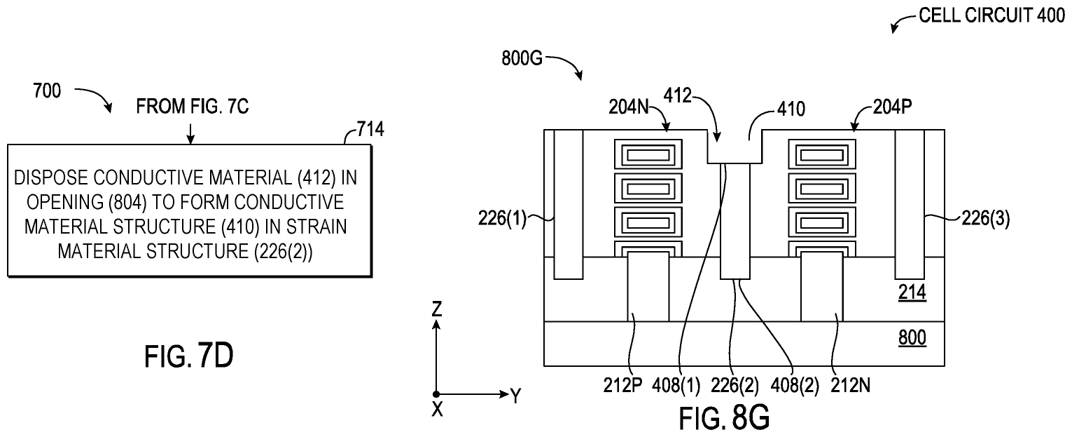

FIGS. 7A-7D is a flowchart illustrating another exemplary fabrication process 700 of fabricating one or more GAA FET devices that include a GAA FET that has an active gate provided by an active region of a gate intersecting a diffusion region where the GAA FET is formed, and wherein a strain material is disposed in an inactive gate region of the gate to apply a strain to the channel of the GAA FET in a direction orthogonal to its channel direction between its source and drain to increase its carrier mobility, including, but not limited to, the GAA NFET devices 202N, 202N(1), 202N(2), 402N, 402N(1), 402N(2) and GAA PFET devices 202P, 202P(1), 202P(2), 402P, 402P(1), 402P(2) in FIGS. 2A-5. FIGS. 8A-8G are exemplary fabrication stages 800A-800G during fabrication of the GAA FET devices according to the exemplary fabrication process 700 in FIGS. 7A-7D. Note that the fabrication process 700 in FIGS. 7A-7D is not limited to fabricating GAA NFET devices 202N, 202N(1), 202N(2), 402N, 402N(1), 402N(2) and GAA PFET devices 202P, 202P(1), 202P(2), 402P, 402P(1), 402P(2) in FIGS. 2A-5. The fabrication process 700 in FIG. 7A-7D is discussed with regard to fabricating the GAA NFET 204N, 404N and GAA PFET 204P, 404P in FIGS. 2A-2B and 4A-4B as a non-limiting example. Also, the fabrication stages 800A-800G in FIGS. 8A-8G are shown as part of fabricating a CMOS circuit like the CMOS circuits 206, 406 in FIGS. 2A-2B and 4A-4B to fabricate one or more NFET devices 202N, 402N and/or PFET devices 202P, 402P therein.

In this regard, as shown in the exemplary fabrication stage 800A in FIG. 8A, a first step of the fabrication process 700 can be to provide or form a substrate 800 on which a semiconductor substrate 214 for a cell circuit can be supported or formed (block 702 in FIG. 7A). As shown in the exemplary fabrication stage 800B in FIG. 8B, a next step of the fabrication process 700 can be to provide or form the semiconductor substrate 214 on the substrate (block 704 in FIG. 7A). Then, the N-type channel structures 228N(1)-228N(3) and P-type channel structures 228P(1)-228P(3) that will serve as respective N-type and P-type channels 218N, 218P for the eventually-formed GAA NFET 204N and GAA PFET 204P are formed (block 704 in FIG. 7A). As shown in FIG. 8B, the N-type channel structures 228N(1)-228N(3) and P-type channel structures 228P(1)-228P(3) are formed from semiconductor layers that were formed and etched into the respective separate N-type channel structures 228N(1)-228N(3) and P-type channel structures 228P(1)-228P(3). Intervening sacrificial layers 802 are also disposed between the N-type channel structures 228N(1)-228N(3) and P-type channel structures 228P(1)-228P(3) as part of the fabrication process, which will later be etched and filled in with gate material of the gate 208.

Then, as shown in the exemplary fabrication stage 800C in FIG. 8C, a next step of the fabrication process 700 can be to form the N-type and P-type channels 218N, 218P that provide the first and second active gates 221N, 221P for the eventually-formed respective GAA NFET 204N and GAA PFET 204P (block 706 in FIG. 7B). The area where the sacrificial layers 802 were disposed as shown in FIG. 8B are etched to allow a gate material 804 of the gate 208 to be disposed therein to surround the N-type channel structures 228N(1)-228N(3) and P-type channel structures 228P(1)-228P(3). Then, as shown in the exemplary fabrication stage 800D in FIG. 8D, a next step of the fabrication process 700 can be to dispose the gate material 804 on the semiconductor substrate 214 and between and surrounding the N-type channel structures 228N(1)-228N(3) and P-type channel structures 228P(1)-228P(3) to form the respective GAA NFET 204N and GAA PFET 204P (block 708 in FIG. 7B).

Then, as shown in the exemplary fabrication stage 800E in FIG. 8E, a next step of the fabrication process 700 can be to form the strain material structures 226(1)-226(3) with strain material 222(1)-222(3) in the inactive gate regions 224(1)-224(3) of the gate 208 to apply strain to the N-type channel 218N and P-type channel 218P in the first direction (Y-axis direction) (block 710 in FIG. 7C). This forms the cell circuit 200 like that shown in FIGS. 2A and 2B. However, if it also desired to couple the first and second active gates 221N, 221P together as discussed above in the cell circuit 400 in FIGS. 4A and 4B, the conductive material structure 410 of conductive material 412 can be disposed in the strain material structure 226(2). This is shown in the exemplary fabrication stages 800F, 800G in FIGS. 8F and 8G. As shown in in the exemplary fabrication stage 800F in FIG. 8F, a next step of the fabrication process 700 can be to form an opening 805 in the strain material structure 226(2) (block 712 in FIG. 7C) to prepare for the conductive material 412 to be disposed in the opening 805 to form the conductive material structure 410. This is shown in the exemplary fabrication stage 800G in FIG. 8G (block 714 in FIG. 7D) where the alternative cell circuit 400 like in FIGS. 4A and 4B is formed.

Note that object being “adjacent” as discussed in this application relates to an object being beside or next to another object with intervening space between them. Adjacent objects may not be physically coupled to each other. Directly adjacent objects means that such objects are directly beside or next to each other without another of the objects being intervening or disposed between the directly adjacent objections. Non-directly adjacent objects means that such objects are not directly beside or next to each other without another of the objects being intervening or disposed between the non-directly adjacent objects.

GAA FET devices that include a GAA PFET and GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in a direction orthogonal to their channel directions between their respective sources and drains, to increase their carrier mobility, including, but not limited to, the GAA FET devices 202, 202N, 202N(1), 202N(2), 202P, 202P(1), 202P(2), 402, 402N, 402N(1), 402N(2), 402P, 402P(1), 402P(2) in FIGS. 2A-5 and 8A-8G, and that can be fabricated according to the exemplary fabrication processes 600, 700 in FIGS. 6-7D, and according to any aspects disclosed herein, may be provided in an IC package provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

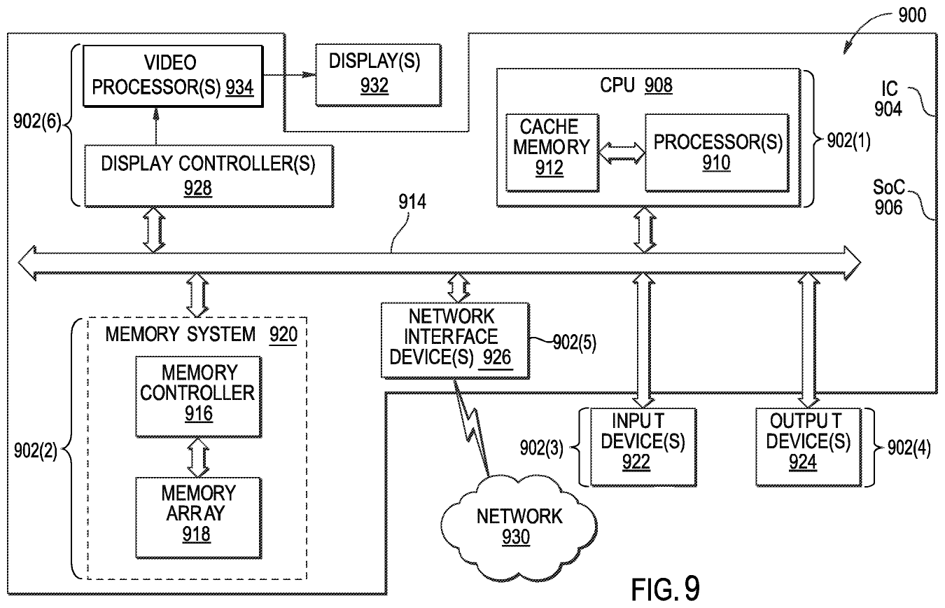

In this regard, FIG. 9 illustrates an example of a processor-based system 900 that includes GAA FET devices 902, 902(1)-902(6) that include a GAA PFET and GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in a direction orthogonal to their channel directions between their respective sources and drains, to increase their carrier mobility, including, but not limited to, the GAA FET devices 202, 202N, 202N(1), 202N(2), 202P, 202P(1), 202P(2), 402, 402N, 402N(1), 402N(2), 402P, 402P(1), 402P(2) in FIGS. 2A-5 and 8A-8G, and that can be fabricated according to the exemplary fabrication processes 600, 700 in FIGS. 6-7D, and according to any aspects disclosed herein. In this example, the processor-based system 900 may be formed as an IC 904 and as a system-on-a-chip (SoC) 906. The processor-based system 900 includes a central processing unit (CPU) 908 that includes one or more processors 910, which may also be referred to as CPU cores or processor cores. The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processors 934, which process the information to be displayed into a format suitable for the display(s) 932. The display(s) 932 can include any type of display, including, but not limited to, a cathode ray tube (CRT), a liquid crystal display (LCD), a plasma display, a light emitting diode (LED) display, etc.

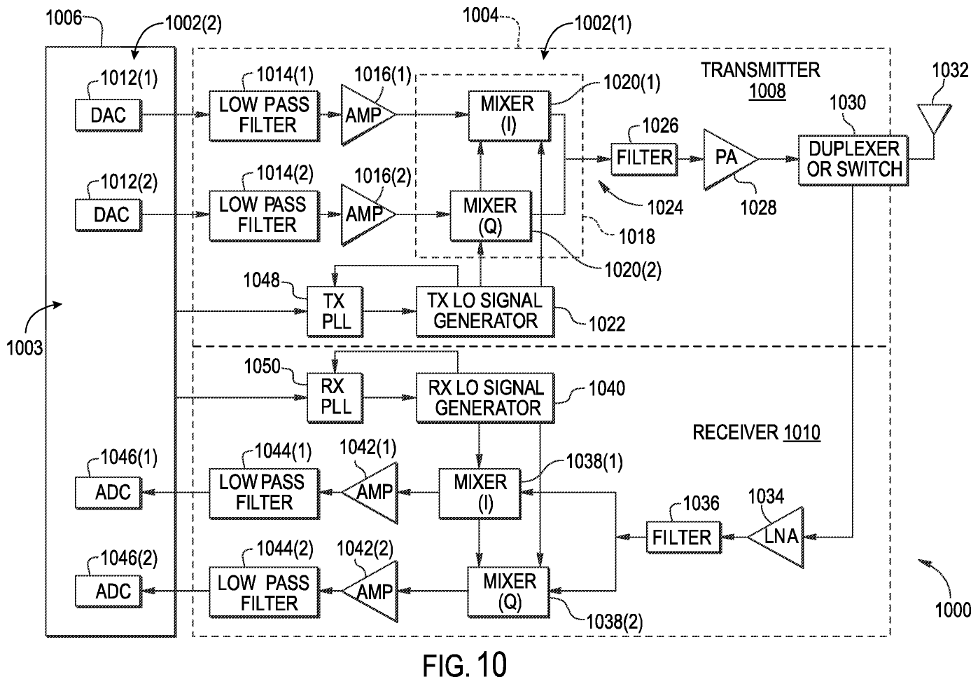

FIG. 10 illustrates an exemplary wireless communications device 1000 that includes radio frequency (RF) components formed from GAA FET devices 1002(1), 1002(2) that include a GAA PFET and GAA NFET that have respective active gates provided by respective active regions of a gate intersecting diffusion regions where the respective GAA PFET and GAA NFET are formed, and wherein strain material is disposed in an inactive gate region(s) of the gate of the same strain type to apply the same type of strain to the channels of the GAA PFET and GAA NFET in a direction orthogonal to their channel directions between their respective sources and drains, to increase their carrier mobility, including, but not limited to, the GAA FET devices 202, 202N, 202N(1), 202N(2), 202P, 202P(1), 202P(2), 402, 402N, 402N(1), 402N(2), 402P, 402P(1), 402P(2) in FIGS. 2A-5 and 8A-8G, and that can be fabricated according to the exemplary fabrication processes 600, 700 in FIGS. 6-7D, and according to any aspects disclosed herein. The wireless communications device 1000 may include or be provided in any of the above-referenced devices, as examples. The wireless communications device 1000 may be provided in an integrated circuit (IC) 1003. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. A gate-all-around (GAA) field-effect transistor (FET) device, comprising:
a semiconductor substrate;
a P-type semiconductor material (P) (P-type) diffusion region in the semiconductor substrate;
an N-type semiconductor material (N) (N-type) diffusion region in the semiconductor substrate;
a gate adjacent to the semiconductor substrate and extending in a first direction, the gate comprising:
   a first active gate region in the P-type diffusion region;
   a second active gate region in the N-type diffusion region; and
   one or more inactive gate regions each outside of the P-type diffusion region and outside of the N-type diffusion region;
a GAA NFET disposed in the P-type diffusion region, the GAA NFET comprising:
   an N-type channel extending in a second direction orthogonal to the first direction, the N-type channel adjacent to a first inactive gate region of the one or more inactive gate regions; and
   a first active gate comprising at least a portion of the first active gate region of the gate surrounding the N-type channel;
a GAA PFET disposed in the N-type diffusion region, the GAA PFET comprising:
   a P-type channel extending in the second direction, the P-type channel adjacent to a second inactive gate region of the one or more inactive gate regions; and
   a second active gate comprising at least a portion of the second active gate region of the gate surrounding the P-type channel; and
a strain material of a first strain type in the first inactive gate region and the second inactive gate region.

2. The GAA FET device of clause 1, wherein:
the strain material is configured to apply a first strain of the first strain type on the N-type channel in the first direction; and
the strain material is configured to apply a second strain of the first strain type on the P-type channel in the first direction.

3. The GAA FET device of clause 1 or 2, wherein the first strain type is a tensile strain.

4. The GAA FET device of any of clauses 1-3, wherein the strain material comprises silicon nitride (SiN).

5. The GAA FET device of any of clauses 1-4, wherein the one or more inactive gate regions further comprise a common inactive gate region between the N-type diffusion region and the P-type diffusion region in the first direction.

6. The GAA FET device of clause 5, further comprising a conductive material disposed in the common inactive gate region to conductively couple the first active gate of the GAA NFET to the second active gate of the GAA PFET.

7. The GAA FET device of clause 6, further comprising:
a strain material structure comprising the strain material in the common inactive gate region; and
wherein:
   the strain material structure comprises a first end adjacent to the semiconductor substrate and a second end opposite the first end.

8. The GAA FET device of clause 7, wherein the conductive material is in the common inactive gate region and coupled to the second end of the strain material structure.

9. The GAA FET device of any of clauses 1-8 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SiP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

10. A method of fabricating a gate-all-around (GAA) field-effect transistor (FET) device, comprising:
forming a P-type semiconductor material (P) (P-type) diffusion region in a semiconductor substrate;
forming an N-type semiconductor material (N) (N-type) diffusion region in the semiconductor substrate;
forming a GAA NFET, comprising:
   forming an N-type channel adjacent to the semiconductor substrate in the P-type diffusion region and extending in a second direction;
forming a GAA PFET, comprising:
   forming a P-type channel adjacent to the semiconductor substrate in the N-type diffusion region and extending in the second direction;
forming a gate adjacent to the semiconductor substrate extending in a first direction orthogonal to the second direction, wherein forming the gate further comprises:
   forming a first active gate region of the gate in the P-type diffusion region comprising a first active gate surrounding the N-type channel;
   forming a second active gate region of the gate in the N-type diffusion region comprising a second active gate surrounding the P-type channel; and
   forming one or more inactive gate regions of the gate outside of the N-type diffusion region and outside of the P-type diffusion region, the one or more inactive gate regions comprising a first inactive gate region adjacent to the N-type channel and a second inactive gate region adjacent to the P-type channel; and
disposing a strain material of a first strain type in the first inactive gate region and the second inactive gate region.

11. The method of clause 10, wherein disposing the strain material comprises:
disposing the strain material of the first strain type in the first inactive gate region applying a first strain of the first strain type on the N-type channel in the first direction; and
disposing the strain material of the first strain type in the second inactive gate region applying a second strain of the first strain type on the P-type channel in the first direction.

12. The method of clause 10 or 11, wherein the first strain type is a tensile strain.

13. The method of any of clauses 10-12, wherein forming the one or more inactive gate regions further comprises:
forming a common inactive gate region between the N-type diffusion region and the P-type diffusion region in the first direction.

14. The method of clause 13, further comprising disposing a conductive material in the common inactive gate region conductively coupling the first active gate to the second active gate.

What is claimed is:

1. A gate-all-around (GAA) field-effect transistor (FET) device, comprising:
a semiconductor substrate;
a P-type semiconductor material (P) (P-type) diffusion region in the semiconductor substrate;
an N-type semiconductor material (N) (N-type) diffusion region in the semiconductor substrate;
a gate adjacent to the semiconductor substrate and extending in a first direction, the gate comprising:
a first active gate region in the P-type diffusion region;
a second active gate region in the N-type diffusion region; and
one or more inactive gate regions each outside of the P-type diffusion region and outside of the N-type diffusion region;
a GAA NFET disposed in the P-type diffusion region, the GAA NFET comprising:
an N-type channel extending in a second direction orthogonal to the first direction, the N-type channel adjacent to a first inactive gate region of the one or more inactive gate regions; and
a first active gate comprising at least a portion of the first active gate region of the gate surrounding the N-type channel;
a GAA PFET disposed in the N-type diffusion region, the GAA PFET comprising:
a P-type channel extending in the second direction, the P-type channel adjacent to a second inactive gate region of the one or more inactive gate regions; and
a second active gate comprising at least a portion of the second active gate region of the gate surrounding the P-type channel; and
a strain material of a first strain type in the first inactive gate region and the second inactive gate region.

2. The GAA FET device of claim 1, wherein:
the strain material is configured to apply a first strain of the first strain type on the N-type channel in the first direction; and
the strain material is configured to apply a second strain of the first strain type on the P-type channel in the first direction.

3. The GAA FET device of claim 1, wherein the first strain type is a tensile strain.

4. The GAA FET device of claim 1, wherein the strain material comprises silicon nitride (SiN).

5. The GAA FET device of claim 1, wherein the one or more inactive gate regions further comprise a common inactive gate region between the N-type diffusion region and the P-type diffusion region in the first direction.

6. The GAA FET device of claim 5, further comprising a conductive material disposed in the common inactive gate region to conductively couple the first active gate of the GAA NFET to the second active gate of the GAA PFET.

7. The GAA FET device of claim 6, further comprising:
a strain material structure comprising the strain material in the common inactive gate region; and
wherein:
the strain material structure comprises a first end adjacent to the semiconductor substrate and a second end opposite the first end.

8. The GAA FET device of claim 7, wherein the conductive material is in the common inactive gate region and coupled to the second end of the strain material structure.

9. The GAA FET device of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SiP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

10. A method of fabricating a gate-all-around (GAA) field-effect transistor (FET) device, comprising:
forming a P-type semiconductor material (P) (P-type) diffusion region in a semiconductor substrate;
forming an N-type semiconductor material (N) (N-type) diffusion region in the semiconductor substrate;
forming a GAA NFET, comprising:
forming an N-type channel adjacent to the semiconductor substrate in the P-type diffusion region and extending in a second direction;
forming a GAA PFET, comprising:
forming a P-type channel adjacent to the semiconductor substrate in the N-type diffusion region and extending in the second direction;
forming a gate adjacent to the semiconductor substrate extending in a first direction orthogonal to the second direction, wherein forming the gate further comprises:
forming a first active gate region of the gate in the P-type diffusion region comprising a first active gate surrounding the N-type channel;
forming a second active gate region of the gate in the N-type diffusion region comprising a second active gate surrounding the P-type channel; and
forming one or more inactive gate regions of the gate outside of the N-type diffusion region and outside of the P-type diffusion region, the one or more inactive gate regions comprising a first inactive gate region adjacent to the N-type channel and a second inactive gate region adjacent to the P-type channel; and
disposing a strain material of a first strain type in the first inactive gate region and the second inactive gate region.

11. The method of claim 10, wherein disposing the strain material comprises:
disposing the strain material of the first strain type in the first inactive gate region applying a first strain of the first strain type on the N-type channel in the first direction; and
disposing the strain material of the first strain type in the second inactive gate region applying a second strain of the first strain type on the P-type channel in the first direction.

12. The method of claim 10, wherein the first strain type is a tensile strain.

13. The method of claim 10, wherein forming the one or more inactive gate regions further comprises:
forming a common inactive gate region between the N-type diffusion region and the P-type diffusion region in the first direction.

14. The method of claim 13, further comprising disposing a conductive material in the common inactive gate region conductively coupling the first active gate to the second active gate.
